(19) United States
(12) Patent Application Publication
(10) Pub. No.: US 2025/0331362 A1
(43) Pub. Date: Oct. 23, 2025

(54) DISPLAY DEVICE AND OPTICAL DEVICE

(71) Applicant: Samsung Display Co., LTD., Yongin-si (KR)

(72) Inventor: Gi Chang LEE, Yongin-si (KR)

(21) Appl. No.: 19/077,587

(22) Filed: Mar. 12, 2025

(30) Foreign Application Priority Data
Apr. 22, 2024 (KR) 10-2024-0053365

(51) Int. Cl. H10K 59/121

(52) U.S. Cl. CPC H10K 59/1213

(57) ABSTRACT

The present disclosure relates to a display device capable of reducing manufacturing costs, and an optical device including the same. According to one or more embodiments, a display device includes a display panel having a display area and a non-display area, a pixel in the display area, and including a pixel circuit, a circuit board connected to the non-display area, a first driving circuit on the display panel, and a second driving circuit on the circuit board, wherein the first driving circuit and the pixel circuit include single-type MOS transistors.

### CROSS-REFERENCE TO RELATED APPLICATION

The present application claims priority to, and the benefit of, Korean Patent Application No. 10-2024-0053365, filed on Apr. 22, 2024, in the Korean Intellectual Property Office, the disclosure of which is incorporated herein by reference.

### BACKGROUND

### 1. Field

The present disclosure relates to a display device capable of reducing manufacturing costs, and an optical device including the same.

### 2. Description of the Related Art

Because an organic light-emitting diode (OLED) display is self-emissive and does not require a separate light source unlike a liquid crystal display, its thickness and weight may be reduced. In addition, an OLED display has garnered attention as a next-generation display for TVs, monitors, and portable electronic devices due to its superior characteristics, such as low power consumption, high luminance, and high response speed.

### SUMMARY

Aspects of the present disclosure provide a display device capable of reducing manufacturing costs, and an optical device including the same.

According to one or more embodiments, a display device includes a display panel having a display area and a non-display area, a pixel in the display area, and including a pixel circuit, a circuit board connected to the non-display area, a first driving circuit on the display panel, and a second driving circuit on the circuit board, wherein the first driving circuit and the pixel circuit include single-type MOS transistors.

The first driving circuit and the pixel circuit of the pixel may include an n-type MOS transistor or a p-type MOS transistor.

The display panel may include a p-type semiconductor substrate, a deep-n-well region of the p-type semiconductor substrate, a p-well region surrounded by the deep-n-well region in plan view, and a p-type MOS transistor on the p-well region.

The p-type MOS transistor may include a source electrode and a drain electrode surrounded by the p-well region in plan view, and a gate electrode above a channel region, and between the source electrode and the drain electrode in plan view. The display panel may include a p-type semiconductor substrate, and an n-

well region of the p-type semiconductor substrate.

The n-type MOS transistor may include a source electrode and a drain electrode surrounded by the n-well region in plan view, and a gate electrode above a channel region, and between the source electrode and the drain electrode in plan view. The circuit board may be arranged along a first edge, a second edge, and a

third edge of the display panel.

The circuit board may be further arranged along a part of a fourth edge of the display panel.

The display panel may further include a first pad at the first edge of the non-display area of the display panel, and connected to the circuit board, and a second pad at the second edge of the non-display area of the display panel, and connected to the circuit board.

The display panel may further include a third pad and a fourth pad at the third edge of the non-display area of the display panel, and connected to the circuit board, and a fifth pad and a sixth pad at the fourth edge of the non-display area of the display panel, and connected to the circuit board.

The circuit board may define an opening between the fifth pad and the sixth pad in plan view.

The pixel may further include a light-emitting element connected to the pixel circuit, and overlapping at least a part of the first driving circuit.

According to one or more embodiments, a display device includes a display panel having a display area and a non-display area, and including a first driving circuit in the non-display area, a pixel in the display area, and including a pixel circuit, a driver facing the display panel, and including a second driving circuit connected to the first driving circuit, wherein the first driving circuit and the pixel circuit include single-type MOS transistors.

The first driving circuit and the pixel circuit may include an n-type MOS transistor or a p-type MOS transistor.

The display panel may include a p-type semiconductor substrate, a deep-n-well region of the p-type semiconductor substrate, a p-well region surrounded by the deep-n-well region in plan view, and a p-type MOS transistor on the p-well region. The p-type MOS transistor may include a source electrode and a drain

electrode surrounded by the p-well region in plan view, and a gate electrode above a channel region, and between the source electrode and the drain electrode in plan view.

The display panel may include a p-type semiconductor substrate, and an n-well region of the p-type semiconductor substrate.

The n-type MOS transistor may include a source electrode and a drain electrode surrounded by the n-well region in plan view, and a gate electrode above a channel region, and between the source electrode and the drain electrode in plan view.

The display panel may include a semiconductor substrate, wherein the driver is above the semiconductor substrate, and faces the semiconductor substrate. The driver may be above the semiconductor substrate and may overlap the display area.

The second driving circuit may be electrically connected to the first driving circuit and to the pixel circuit through a through hole penetrating the semiconductor substrate.

The display device may further include a connection electrode in the through hole, and a routing line electrically connecting the connection electrode, the second driving circuit, and the pixel circuit.

The second driving circuit may include a CMOS transistor.

The driver may include a p-type semiconductor substrate, a deep-n-well region of the p-type semiconductor substrate, an n-well region on the deep-n-well region, and a p-well region on the deep-n-well region.

The CMOS transistor may include a p-type MOS transistor on the n-well region, and an n-type MOS transistor on the p-well region.

The pixel may further include a light-emitting element connected to the pixel circuit, and overlapping at least a part of the first driving circuit.

According to one or more embodiments, an optical device includes a display device including a display panel having a display area and a non-display area, a pixel in the display area, and including a pixel circuit, a circuit board connected to the non-display area, a first driving circuit on the display panel, and a second driving circuit on the circuit board, and an optical-path-changing member on the display device, wherein the first driving circuit and the pixel circuit include single-type MOS transistors.

According to one or more embodiments, an optical device includes a display device including a display panel having a display area and a non-display area, and including a first driving circuit in the non-display area, a pixel in the display area, and including a pixel circuit, and a driver facing the display panel, and including a second driving circuit connected to the first driving circuit, and an optical-path-changing member on the display device, wherein the first driving circuit and the pixel circuit include single-type MOS transistors.

According to the display device and the optical device of the present disclosure, the manufacturing cost can be reduced.

In addition, according to the display device and the optical device of the present disclosure, the display area can be expanded.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects of the present disclosure will become more apparent by describing in detail embodiments thereof with reference to the attached drawings, in which:

FIG. 1 is an exploded perspective view showing a display device according to one or more embodiments;

FIG. 2 is a block diagram illustrating a display device according to one or more embodiments;

FIG. 3 is an equivalent circuit diagram illustrating a first pixel according to one or more embodiments;

FIG. 4 is a layout diagram showing an example of the display panel according to one or more embodiments;

FIG. 5 is a layout diagram showing a display device with a circuit board connected to the display panel of FIG. 4;

FIG. 6 is a detailed configuration diagram of the scan shift register of FIG. 4;

FIG. 7 is a detailed configuration diagram of the emission shift register of FIG. 4;

FIG. 8 is a detailed configuration diagram of the first distribution circuit of FIG. 4;

FIGS. 9 and 10 are layout diagrams illustrating embodiments of the display area of FIG. 4;

FIG. 11 is a cross-sectional view illustrating an example of the display panel 100 taken along the line 11-11′ of FIG. 9;

FIG. 12 is a cross-sectional view of an n-type MOS transistor;

FIG. 13 is a cross-sectional view of a p-type MOS transistor;

FIG. 14 is an exploded perspective view showing the display device according to one or more embodiments;

FIG. 15 is a plan view of the display device of FIG. 14 viewed from above a display panel;

FIG. 16 is a plan view of the display device of FIG. 14 viewed from a driver;

FIG. 17 is a diagram for describing electrical connection between the display panel and the driver;

FIG. 18 is a cross-sectional view of the driver of FIG. 14;

FIG. 19 is a cross-sectional view of the display device of FIG. 14;

FIG. 20 is a plan view of the display panel according to one or more embodiments;

FIG. 21 is a plan view of the display panel according to one or more embodiments;

FIG. 22 is a perspective view illustrating a head-mounted display according to one or more embodiments;

FIG. 23 is an exploded perspective view illustrating an example of the head-mounted display of FIG. 22; and

FIG. 24 is a perspective view illustrating a head-mounted display according to one or more embodiments.

FIG. 25 is a block diagram of an electronic device according to one embodiment.

FIGS. 26, 27 and 28 are schematic diagrams of electronic devices according to various embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied. In the drawings, the relative sizes of elements, layers, and regions may be

exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present.

The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

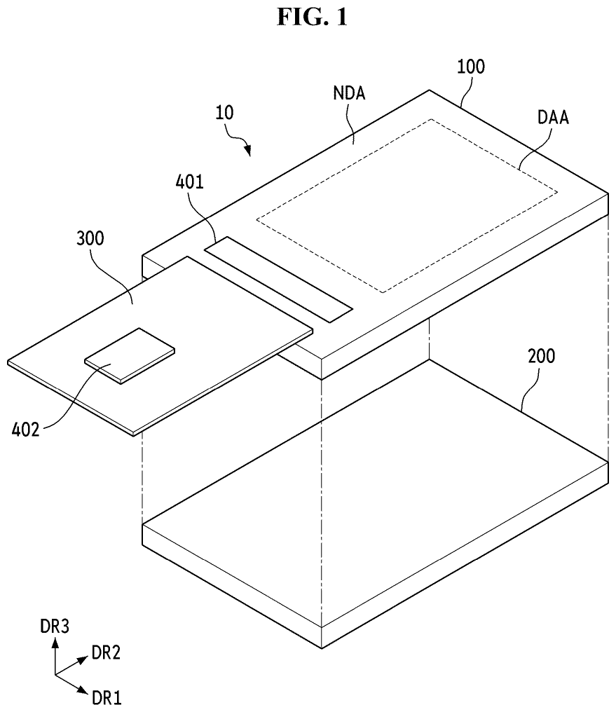

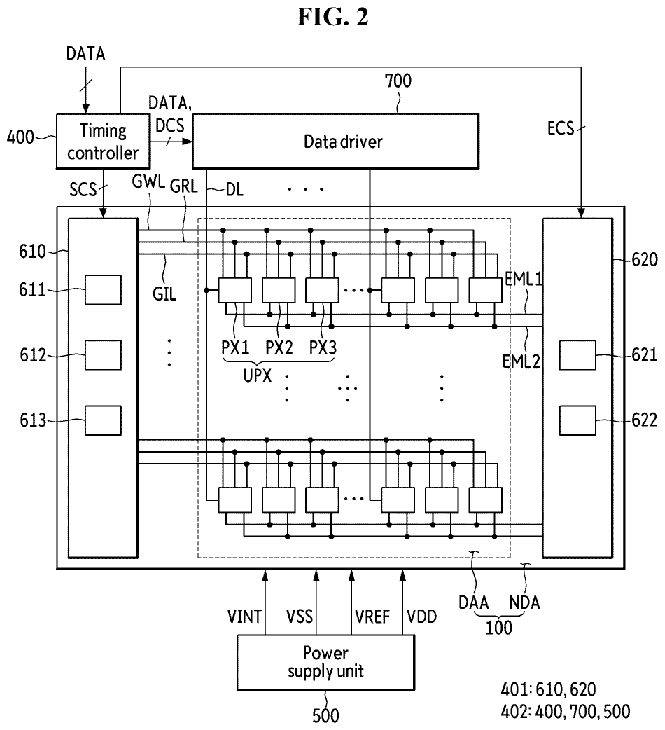

FIG. 1 is an exploded perspective view showing a display device according to one or more embodiments. FIG. 2 is a block diagram illustrating a display device according to one or more embodiments.

Referring to FIGS. 1 and 2, a display device 10 according to one or more embodiments is a device displaying a moving image or a still image. The display device 10 according to one or more embodiments may be applied to portable electronic devices, such as a mobile phone, a smartphone, a tablet personal computer, a mobile communication terminal, an electronic organizer, an electronic book, a portable multimedia player (PMP), a navigation system, an ultra-mobile PC (UMPC) or the like. For example, the display device 10 according to one or more embodiments may be applied as a display unit of a television, a laptop, a monitor, a billboard, or an Internet-of-Things (IoT) terminal. Alternatively, the display device 10 according to one or more embodiments may be applied to a smart watch, a watch phone, a head-mounted display (HMD) for implementing virtual reality and augmented reality, and the like. The display device 10 according to one or more embodiments may include a

display panel 100 having a first driving circuit 401 (or internal driving circuit), a heat dissipation layer 200, a circuit board 300, and a second driving circuit 402 (or external driving circuit). In this case, the second driving circuit 402 may include a timing control circuit 400 and a data driver 700. Additionally, the second driving circuit 402 may further include a power supply circuit 500 in addition to the timing control circuit 400 and the data driver 700.

The display panel 100 may have a planar shape similar to a quadrilateral shape. For example, the display panel 100 may have a planar shape similar to a quadrilateral shape, having a short side of a first direction DR1 and a long side of a second direction DR2 crossing the first direction DR1. In the display panel 100, a corner where a short side in the first direction DR1 and a long side in the second direction DR2 meet may be right-angled or rounded with a curvature (e.g., predetermined curvature). The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the present disclosure is not limited thereto.

The display panel 100 may include a display area DAA displaying an image and a non-display area NDA not displaying an image as shown in FIGS. 1 and 2.

A plurality of pixels PX, a plurality of scan lines SL, a plurality of emission control lines EML, and a plurality of data lines DL may be located in the display area DAA of the display panel 100.

The plurality of pixels PX may be arranged in a matrix form in the first direction DR1 and the second direction DR2. The plurality of scan lines SL and the plurality of emission control lines EML may extend in the first direction DR1, while being located in the second direction DR2. The plurality of data lines DL may extend in the second direction DR2, while being located in the first direction DR1.

The plurality of scan lines SL include a plurality of write scan lines GWL, a plurality of reset scan lines GRL, and a plurality of initialization scan lines GIL. The plurality of emission control lines EML include a plurality of first emission control lines EML1 and a plurality of second emission control lines EML2.

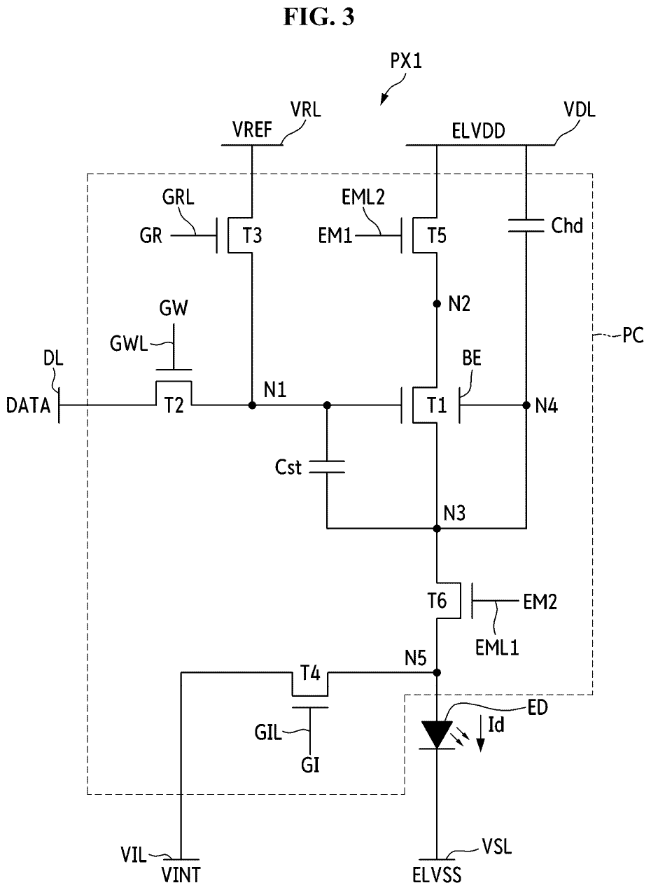

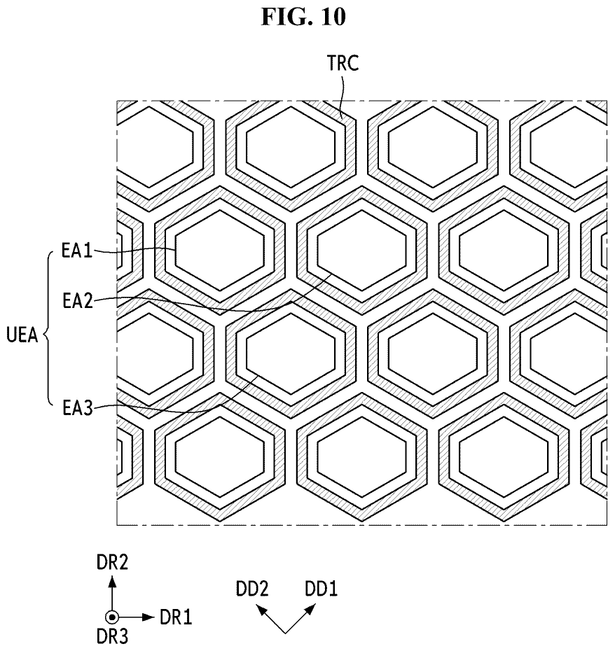

Each of a plurality of unit pixels UPX includes a plurality of pixels PX1, PX2, and PX3. The plurality of pixels PX1, PX2, and PX3 may include a plurality of pixel transistors (e.g., T1, T2, T3, T4, T5, and T6) as shown in FIG. 3, and the plurality of pixel transistors are formed through a semiconductor process, and may be located on (as used herein, “located on” may mean “above”) a semiconductor substrate SSUB (see FIG. 10). For example, the plurality of pixel transistors may be formed of a metal oxide semiconductor (MOS). For example, the pixel transistors may be formed as p-type MOS transistors or n-type MOS transistors.

Each of the plurality of pixels PX1, PX2, and PX3 may be connected to any one of the plurality of write scan lines GWL, any one of the plurality of reset scan lines GRL, any one of the plurality of initialization scan lines GIL, any one of the plurality of first emission control lines EML1, any one of the plurality of second emission control lines EML2, and any one of the plurality of data lines DL. Each of the plurality of pixels PX1, PX2, and PX3 may receive a data voltage of the data line DL in response to a write scan signal of the write scan line GWL, and may emit light from the light-emitting element according to the data voltage.

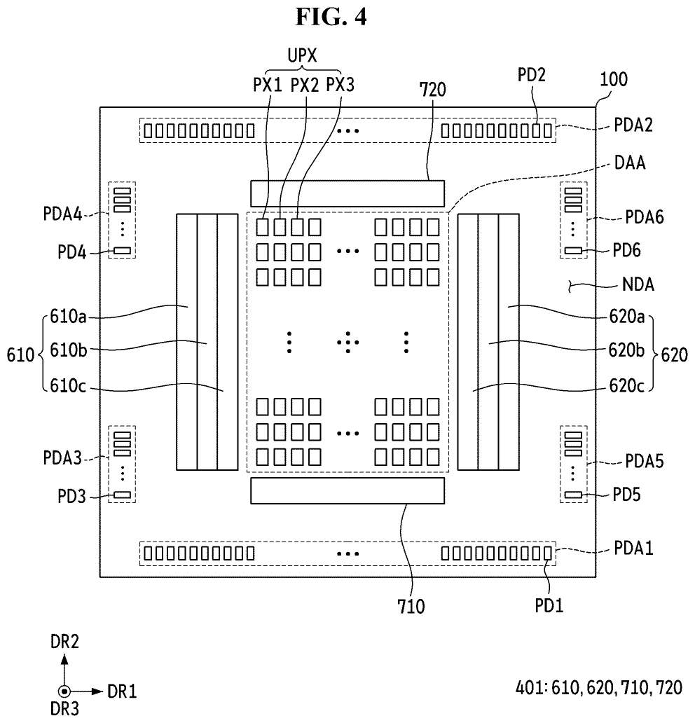

The first driving circuit 401 may be located in the non-display area NDA of the display panel 100. The first driving circuit 401 may include, for example, a scan driver 610 and an emission driver 620. In addition, the first driving circuit 401 may further include a first distribution circuit 710 (see FIG. 4) and a second distribution circuit 720 (see FIG. 4), in addition to the scan driver 610 and the emission driver 620 described above.

The scan driver 610 may include a plurality of scan transistors, and the emission driver 620 may include a plurality of light-emitting transistors. The plurality of scan transistors and the plurality of light-emitting transistors may be formed on the semiconductor substrate SSUB (see FIG. 10) through a semiconductor process. For example, the plurality of scan transistors and the plurality of light-emitting transistors may be formed as p-type MOS transistors or n-type MOS transistors. Although it is illustrated in FIG. 2 that the scan driver 610 is located on the left side of the display area DAA, and that the emission driver 620 is located on the right side of the display area DAA, the present disclosure is not limited thereto. For example, the scan driver 610 and the emission driver 620 may be located on both the left side and/or the right side of the display area DAA.

The scan driver 610 may include a write scan signal output unit 611, a reset scan signal output unit 612, and an initialization scan signal output unit 613. Each of the write scan signal output unit 611, the reset scan signal output unit 612, and the initialization scan signal output unit 613 may receive a scan-timing control signal SCS from the timing control circuit 400. The write scan signal output unit 611 may generate write scan signals according to the scan-timing control signal SCS of the timing control circuit 400, and may output them sequentially to the write scan lines GWL. The reset scan signal output unit 612 may generate reset scan signals in response to the scan-timing control signal SCS, and may sequentially output them to the reset scan lines GRL. The initialization scan signal output unit 613 may generate initialization scan signals in response to the scan-timing control signal SCS, and may sequentially output them to the initialization scan lines GIL.

The emission driver 620 includes a first emission control driver 621 and a second emission control driver 622. Each of the first emission control driver 621 and the second emission control driver 622 may receive an emission-timing control signal ECS from the timing control circuit 400. The first emission control driver 621 may generate first emission control signals according to the emission-timing control signal ECS, and may sequentially output them to the first emission control lines EML1. The second emission control driver 622 may generate second emission control signals according to the emission-timing control signal ECS, and may sequentially output them to the second emission control lines EML2.

The data driver 700 may receive digital video data DATA and a data-timing control signal DCS from the timing control circuit 400. The data driver 700 converts the digital video data DATA into analog data voltages according to the data-timing control signal DCS, and outputs the analog data voltages to the data lines DL. In this case, the pixels PX1, PX2, and PX3 are selected by the write scan signal of the scan driver 610, and data voltages may be supplied to the selected pixels PX1, PX2, and PX3.

The heat dissipation layer 200 may overlap the display panel 100 in a third direction DR3, which is the thickness direction of the display panel 100. The heat dissipation layer 200 may be located on one surface of the display panel 100, for example, on the rear surface thereof. The heat dissipation layer 200 serves to dissipate heat generated from the display panel 100. The heat dissipation layer 200 may include a metal layer, such as graphite, silver (Ag), copper (Cu), or aluminum (Al) having high thermal conductivity.

The circuit board 300 may be electrically connected to a plurality of first pads PD1 (see FIG. 4) of a first pad portion PDA1 (see FIG. 4) of the display panel 100 by using a conductive adhesive member, such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be located on the rear surface of the display panel 100 and/or the rear surface of the heat dissipation layer 200. One end of the circuit board 300 may be an opposite end of the other end of the circuit board 300 connected to the plurality of first pads PD1 (see FIG. 4) of the first pad portion PDA1 (see FIG. 4) of the display panel 100 by using a conductive adhesive member.

The timing control circuit 400 may receive digital video data and timing signals inputted from the outside. The timing control circuit 400 may generate the scan-timing control signal SCS, the emission-timing control signal ECS, and the data-timing control signal DCS for controlling the display panel 100 in response to the timing signals. The timing control circuit 400 may output the scan-timing control signal SCS to the scan driver 610, and may output the emission-timing control signal ECS to the emission driver 620. The timing control circuit 400 may output the digital video data and the data-timing control signal DCS to the data driver 700.

The power supply circuit 500 may generate a plurality of panel-driving voltages according to a power voltage from the outside. For example, the power supply circuit 500 may generate a common voltage ELVSS, a driving voltage ELVDD, a reference voltage VREF, and an initialization voltage VINT, and may supply them to the display panel 100. The common voltage ELVSS, the driving voltage ELVDD, the reference voltage VREF, and the initialization voltage VINT will be described later in conjunction with FIG. 3.

The second driving circuit 402, which includes the timing control circuit 400, the power supply circuit 500, and the data driver 700, may be formed as an integrated circuit (IC) and attached to one surface of the circuit board 300. In this case, the scan-timing control signal SCS and the emission-timing control signal ECS from the timing control circuit 400 and the data voltages from the data driver 700 may be supplied to the display panel 100 through the circuit board 300. In addition, the common voltage ELVSS, the driving voltage ELVDD, the reference voltage VREF, and the initialization voltage VINT from the power supply circuit 500 may be supplied to the display panel 100 through the circuit board 300.

FIG. 3 is an equivalent circuit diagram illustrating a first pixel PX1 according to one or more embodiments.

As shown in FIG. 3, the pixel PX may include a light-emitting element ED and a pixel circuit PC connected to the light-emitting element ED. The light-emitting element ED is a light source of the pixel PX, and it may be, for example, an organic light-emitting diode, but is not limited thereto.

The pixel circuit PC may include pixel transistors (e.g., the first to sixth transistors T1 to T6), a first capacitor Cst, and a second capacitor Chd.

The pixel circuit PC may supply a driving current Id to the light-emitting element ED in response to scan signals, emission control signals, and data signals supplied from the scan driver 610, the emission driver 620, and the data driver 700, respectively. For example, the pixel circuit PC may supply the driving current Id to the light-emitting element ED in response to scan signals GW, GR, and GI supplied from the scan driver 610 through the respective scan lines GWL, GRL, and GIL, emission control signals EM1 and EM2 supplied from the emission driver 620 through the respective emission control lines EML1 and EML2, and a data signal DATA supplied from the data driver 700 through the data line DL.

The first transistor T1 may be a driving transistor of the pixel PX whose magnitude of a drain-source current (e.g., the driving current Id) is determined depending on a gate-source voltage. The second, third, fourth, fifth, and sixth transistors T2, T3, T4, T5, and T6 may be switching transistors that are turned on or off depending on respective gate-source voltages.

The pixel PX may be connected to the write scan line GWL that transmits a write scan signal GW (e.g., a scan signal), the initialization scan line GIL that transmits an initialization scan signal GI, the reset scan line GRL that transmits a reset scan signal GR, the first emission control line EML1 that transmits a first emission control signal EM1, the second emission control line EML2 that transmits a second emission control signal EM2, and the data line DL that transmits the data signal DATA. In addition, the pixel PX may be connected to a driving power line VDL that transmits the driving voltage ELVDD and a common power line VSL that transmits the common voltage ELVSS. In one or more embodiments, the pixel PX may be further connected to an initialization power line VIL that transmits the initialization voltage VINT and a reference power line VRL that transmits the reference voltage VREF.

The first transistor T1 may include a gate electrode connected to a first node N1, a drain electrode connected to a second node N2, and a source electrode connected to a third node N3. The drain electrode of the first transistor T1 may be connected to the driving power line VDL via the fifth transistor T5, and the source electrode thereof may be connected to the light-emitting element ED via the sixth transistor T6. The first transistor T1 may control the magnitude (e.g., current amount) of the driving current Id flowing to the light-emitting element ED to correspond to the data signal DATA transmitted to the first node N1. In one or more embodiments, the body electrode of the first transistor T1 may be connected to a fourth node N4.

The second transistor T2 may include a gate electrode connected to the write scan line GWL, a drain electrode connected to the data line DL, and a source electrode connected to the first node N1. The second transistor T2 may be turned on by the write scan signal GW transmitted through the write scan line GWL to connect the data line DL with the first node N1. Accordingly, the data signal DATA transmitted through the data line DL may be sent to the first node N1.

The third transistor T3 may include a gate electrode connected to the reset scan line GRL, a source electrode connected to the reference power line VRL, and a drain electrode connected to the first node N1. The third transistor T3 may be turned on by the reset scan signal GR transmitted through the reset scan line GRL, and may transmit the reference voltage VREF transmitted through the reference power line VRL to the first node N1.

The fourth transistor T4 may include a gate electrode connected to the initialization scan line GIL, a drain electrode connected to a fifth node N5, and a source electrode connected to the initialization power line VIL. The fourth transistor T4 may be turned on by the initialization scan signal GI transmitted through the initialization scan line GIL, and may transmit the initialization voltage VINT transmitted through the initialization power line VIL to the fifth node N5.

The fifth transistor T5 may include a gate electrode connected to the first emission control line EML1, a drain electrode connected to the driving power line VDL, and a source electrode connected to the second node N2. The fifth transistor T5 may be turned on by the first emission control signal EM1 transmitted through the first emission control line EML1 to control the emission timing of the pixel PX.

The sixth transistor T6 may include a gate electrode connected to the second emission control line EML2, a drain electrode connected to the third node N3, and a source electrode connected to the fifth node N5. The sixth transistor T6 may be turned on by the second emission control signal EM2 transmitted through the second emission control line EML2 to control the emission timing of the pixel PX.

The first capacitor Cst may be connected between the first node N1 and the third node N3. The first capacitor Cst is a storage capacitor of the pixel PX, and may store therein a threshold voltage of the first transistor T1 and a voltage corresponding to the data signal DATA (e.g., a data voltage).

The second capacitor Chd may be connected between the driving power line VDL and the fourth node N4. In one or more embodiments, the capacitance of the second capacitor Chd may be less than that of the first capacitor Cst.

The light-emitting element ED may be connected between the fifth node N5 and the common power line VSL. For example, the light-emitting element ED may include a first electrode (e.g., an anode electrode or a pixel electrode) connected to the fifth node N5, a second electrode (e.g., a cathode electrode or a common electrode) facing the first electrode and connected to the common power line VSL, and a light-emitting layer interposed between the first electrode and the second electrode. In one or more embodiments, the first electrode of the light-emitting element ED may be an individual electrode individually provided in each pixel PX, and the second electrode of the light-emitting element ED may be a common electrode shared by the plurality of pixels PX. The light-emitting element ED may emit light with a luminance corresponding to the driving current Id during a time period in which the driving current Id is supplied from the pixel circuit PC.

Each of the first to sixth transistors T1 to T6 may be a metal-oxide-semiconductor field effect transistor (MOSFET). For example, each of the first to sixth transistors T1 to T6 may be a p-type MOSFET, but the present disclosure is not limited thereto. Each of the first to sixth transistors T1 to T6 may be an n-type MOSFET.

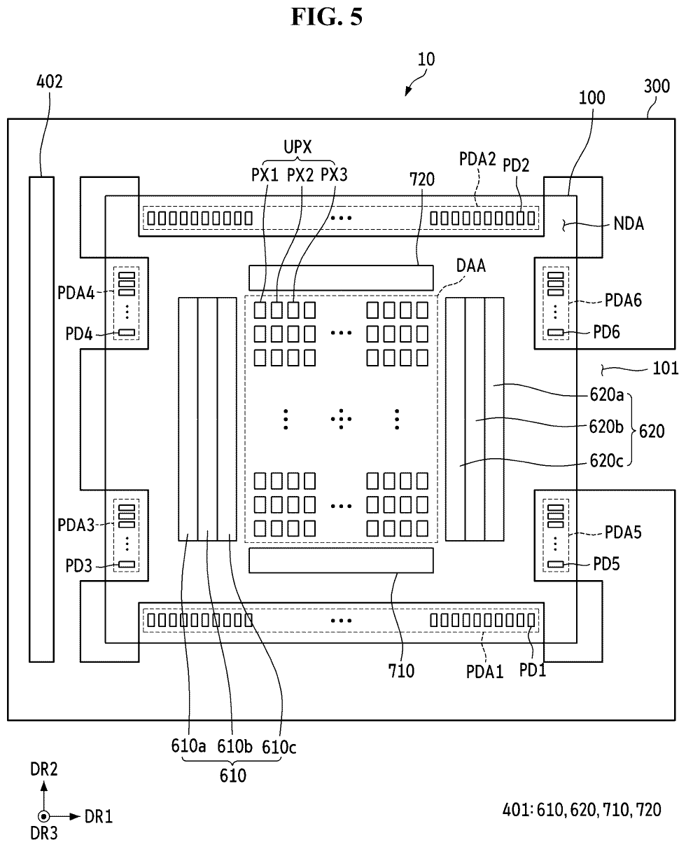

FIG. 4 is a layout diagram showing an example of the display panel 100 according to one or more embodiments, and FIG. 5 is a layout diagram showing a display device with a circuit board connected to the display panel 100 of FIG. 4.

Referring to FIG. 4, the display area DAA of the display panel 100 according to one or more embodiments may include the plurality of pixels PX arranged in a matrix form. The scan driver 610, the emission driver 620, the first distribution circuit 710, the second distribution circuit 720, the first pad portion PDA1, a second pad portion PDA2, a third pad portion PDA3, a fourth pad portion PDA4, a fifth pad portion PDA5, and a sixth pad portion PDA6 may be located in the non-display area NDA of the display panel 100 according to one or more embodiments.

The scan driver 610 may be located on the first side of the display area DAA, and the emission driver 620 may be located on the second side of the display area DAA. For example, the scan driver 610 may be located in the non-display area NDA located on the left side of the display area DAA, and the emission driver 620 may be located in the non-display area NDA located on the right side of the display area DAA.

The scan driver 610 may include a scan shift register 610a, a scan level shifter 610b, and a scan buffer 610c.

The scan shift register 610a may receive a scan shift clock and a scan start pulse from the timing control circuit 400, and may sequentially generate a plurality of scan signals while shifting the scan start pulse for each cycle of the scan shift clock.

The scan level shifter 610b may convert the levels of the plurality of scan signals from the scan shift register 610a, and may provide them to the scan buffer 610c.

The scan buffer 610c may buffer and output the plurality of scan signals from the scan level shifter 610b.

The emission driver 620 may include an emission shift register 620a, an emission level shifter 620b, and an emission buffer 620c.

The emission shift register 620a may receive an emission shift clock and an emission start pulse from the timing control circuit 400, and may sequentially generate a plurality of emission control signals while shifting the emission start pulse for each cycle of the emission shift clock.

The emission level shifter 620b may convert the levels of the plurality of emission control signals from the emission shift register 620a, and may provide them to the emission buffer 620c.

The emission buffer 620c may buffer and output the plurality of emission control signals from the emission level shifter 620b.

The first pad portion PDA1 may include a plurality of first pads PD1 connected to pads of the circuit board 300 through a conductive adhesive member. The first pad portion PDA1 may be located at the third edge of the display area DAA. For example, the first pad portion PDA1 may be located in the non-display area NDA located at the lower edge of the display area DAA.

The second pad portion PDA2 may include a plurality of second pads PD2 connected to pads of the circuit board 300 through a conductive adhesive member. The second pad portion PDA2 may be located at the fourth edge of the display area DAA. For example, the second pad portion PDA2 may be located in the non-display area NDA located at the upper edge of the display area DAA.

The third pad portion PDA3 may include a plurality of third pads PD3 connected to the pads of the circuit board 300 via a conductive adhesive member. The fourth pad portion PDA4 may include a plurality of fourth pads PD4 connected to the pads of the circuit board 300 via a conductive adhesive member. The third pad portion PDA3 and the fourth pad portion PDA4 may be located at the first edge of the display panel 100. For example, the third pad portion PDA3 and the fourth pad portion PDA4 may be located in the non-display area NDA located at the left edge of the display panel 100.

The fifth pad portion PDA5 may include a plurality of fifth pads PD5 connected to the pads of the circuit board 300 via a conductive adhesive member. The sixth pad portion PDA6 may include a plurality of sixth pads PD6 connected to the pads of the circuit board 300 via a conductive adhesive member. The fifth pad portion PDA5 and the sixth pad portion PDA6 may be located at the second edge of the display panel 100. For example, the fifth pad portion PDA5 and the sixth pad portion PDA6 may be located in the non-display area NDA located at the right edge of the display panel 100.

The first distribution circuit 710 may distribute data voltages applied through the first pad portion PDA1 to the plurality of data lines DL. For example, the first distribution circuit 710 may distribute the data voltages applied through one first pad PD1 of the first pad portion PDA1 to the k (k is a positive integer of 2 or more) data lines DL, and as a result, the number of the plurality of first pads PD1 may be reduced. The first distribution circuit 710 may be located on the third side of the display area DAA of the display panel 100. For example, the first distribution circuit 710 may be located in the non-display area NDA located on the lower side of the display area DAA. The first distribution circuit 710 may include a plurality of first distribution transistors. The plurality of first distribution transistors may be formed through a semiconductor process, and may be formed on the semiconductor substrate SSUB (see FIG. 10). For example, the plurality of first distribution transistors may be formed as p-type MOS transistors or n-type MOS transistors.

The second distribution circuit 720 may distribute signals applied through the second pad portion PDA2 to the scan driver 610, the emission driver 620, and the data lines DL. The second distribution circuit 720 may be located on the fourth side of the display area DAA of the display panel 100. For example, the second distribution circuit 720 may be located in the non-display area NDA located on the upper side of the display area DAA. The second distribution circuit 720 may include a plurality of second distribution transistors. The plurality of second distribution transistors may be formed through a semiconductor process, and may be formed on the semiconductor substrate SSUB (see FIG. 10). For example, the plurality of second distribution transistors may be formed as p-type MOS transistors or n-type MOS transistors.

Each of the third pad portion PDA3, the fourth pad portion PDA4, the fifth pad portion PDA5, and the sixth pad portion PDA6 may be an auxiliary pad portion. The circuit board 300 may be further connected to at least one of the third to sixth pad portions PDA3 to PDA6. The circuit board 300 may supply to the display panel 100 the data voltages, scan-timing control signal SCS, emission-timing control signal, and panel-driving voltage signals (e.g., the voltages ELVDD, ELVSS, VREF, and VINT) supplied from the aforementioned second driving circuit 402 through at least one of the third to sixth pad portions PDA3 to PDA6.

As shown in FIG. 5, the circuit board 300 may be connected to the first pad portion PDA1 and the second pad portion PDA2 of the display panel 100. In addition, the circuit board 300 may be further connected to at least one of the third to sixth pad portions PDA3 to PDA6.

The circuit board 300 may be located along the first, second, and third edges of the display panel 100. Further, the circuit board may be located along a part of the fourth edge of the display panel 100. The circuit board 300 may have/define an opening 101 between the fifth pad PD5 and the sixth pad PD6. For example, the circuit board 300 may have the opening 101 between the fifth pad portion PDA5 where the plurality of fifth pads PD5 are located and the sixth pad portion PDA6 where the plurality of sixth pads PD6 are located.

Meanwhile, in one or more other embodiments, in plan view, the circuit board 300 may surround the display panel 100. For example, the outer edge of the circuit board 300 may surround the outer edge of the display panel 100 in plan view.

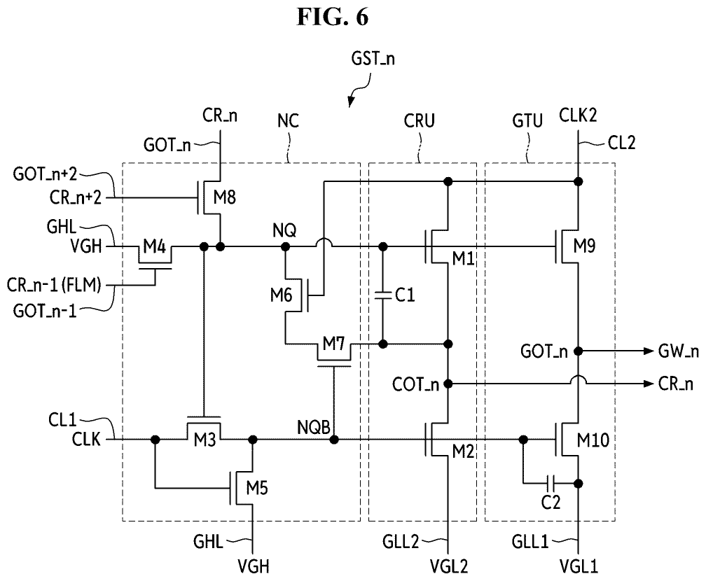

FIG. 6 is a detailed configuration diagram of the scan shift register 610a of FIG. 4.

The scan shift register 610a may include a plurality of scan stages that sequentially output the scan signals. In this case, because the configurations of the scan stages are the same, the configuration of one n^{th} scan stage GST_n will be representatively described.

As shown in FIG. 6, the n^{th} scan stage GST_n may include a node control unit NC, a carry output unit CRU, and a gate output unit GTU.

The n^{th} scan stage GST_n may include first to tenth transistors M1 to M10, a first capacitor C1, and a second capacitor C2. For example, the node control unit NC may include the third to eighth transistors M3 to M8. The carry output unit CRU may include the first transistor M1 and the second transistor M2. The gate output unit GTU may include the ninth transistor M9 and the tenth transistor M10. In this case, the ninth transistor M9 and the tenth transistor M10 may be output transistors that output the n^{th} write scan signal GW_n. For example, the ninth transistor M9 may be a pull-up transistor and the tenth transistor M10 may be a pull-down transistor.

A gate electrode of the first transistor M1 may be connected to a set node NQ, a drain electrode of the first transistor M1 may be connected to the second clock line CL2 to receive a second clock signal CLK2, and a source node of the first transistor M1 may be connected to a carry output terminal COT_n to output a carry output signal CR_n.

A gate electrode of the second transistor M2 may be connected to a reset node NQB, a drain electrode of the second transistor M2 may be connected to the carry output terminal COT_n, and a source electrode of the second transistor M2 may be connected to a second gate low voltage line GLL2 to receive a second gate low voltage VGL2.

A gate electrode of the third transistor M3 may be connected to the set node NQ, a drain electrode of the third transistor M3 may be connected to a first clock line CL1 to receive a first clock signal CLK1, and a source electrode of the third transistor M3 may be connected to the reset node NQB.

A gate electrode of the fourth transistor M4 may be connected to a start signal line or to a carry output terminal COT_n−1 of the (n−1)^{th} stage to receive a carry output signal CR_n−1(FLM), a drain electrode of the fourth transistor M4 may be connected to a gate high voltage line GHL to receive a gate high voltage VGH, and a source electrode of the fourth transistor M4 may be connected to the set node NQ. In this case, the frame line mark signal described above may be applied to the start signal line, for example.

A gate electrode of the fifth transistor M5 may be connected to the first clock line CL1, a drain electrode of the fifth transistor M5 may be connected to the gate high voltage line GHL, and a source electrode of the fifth transistor M5 may be connected to the reset node NQB.

A gate electrode of the sixth transistor M6 may be connected to the second clock line CL2, a drain electrode of the sixth transistor M6 may be connected to the set node NQ, and a source electrode of the sixth transistor M6 may be connected to a source electrode of the seventh transistor M7.

A gate electrode of the seventh transistor M7 may be connected to the reset node NQB, a drain electrode of the seventh transistor M7 may be connected to the carry output terminal COT_n, and the source electrode of the seventh transistor M7 may be connected to the source electrode of the sixth transistor M6.

A gate electrode of the eighth transistor M8 may be connected to a carry output terminal COT_n+2 of the (n+2)^{th} stage to receive a carry output signal CR_n+2, a drain electrode of the eighth transistor M8 may be connected to the set node NQ, and a source electrode of the eighth transistor M8 may be connected to the carry output terminal COT_n.

A gate electrode of the ninth transistor M9 may be connected to the set node NQ, a drain electrode of the ninth transistor M9 may be connected to the second clock line CL2, and a source electrode of the ninth transistor M9 may be connected to a scan output terminal GOT_n to output an emission control signal EM_n.

A gate electrode of the tenth transistor M10 may be connected to the reset node NQB, a drain electrode of the tenth transistor M10 may be connected to the scan output terminal GOT_n to output an emission control signal EM_n, and a source electrode of the tenth transistor M10 may be connected to a first gate low voltage line GLL1 to receive a first gate low voltage VGL1.

The first electrode of the first capacitor C1 may be connected to the set node NQ, and the second electrode of the first capacitor C1 may be connected to the carry output terminal COT_n.

The first electrode of the second capacitor C2 may be connected to the reset node NQB, and the second electrode of the second capacitor C2 may be connected to the first gate low voltage line GLL1.

The first to tenth transistors M1 to M10 of FIG. 6 may be formed as n-type MOS transistors or p-type MOS transistors.

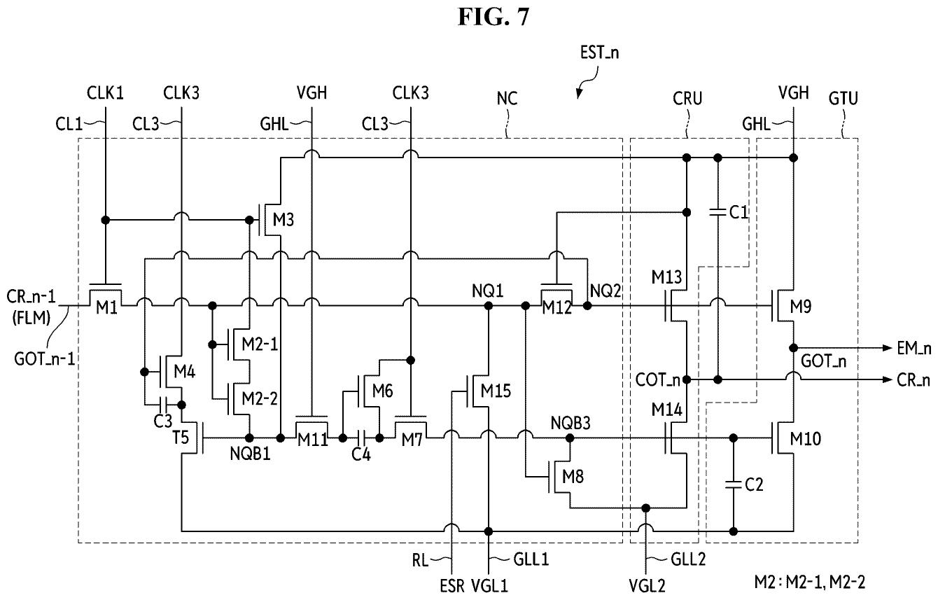

FIG. 7 is a detailed configuration diagram of the emission shift register 620a of FIG. 4.

The emission shift register 620a may include a plurality of emission stages that sequentially output the emission control signals. In this case, because the configurations of the emission stages are the same, the configuration of one n^{th} emission stage EST_n will be representatively described.

As shown in FIG. 7, the n^{th} emission stage EST_n may include a node control unit NC, a carry output unit CRU, and a gate output unit GTU.

The n^{th} emission stage EST_n may include first to fifteenth transistors M1 to M15, a first capacitor C1, a second capacitor C2, a third capacitor C3, and a fourth capacitor C4. For example, the node control unit NC may include the first to eighth, eleventh, twelfth, and fifteenth transistors M1 to M8, M11, M12, and M15. The carry output unit CRU may include a thirteenth transistor M13 and a fourteenth transistor M14. The gate output unit GTU may include the ninth transistor M9 and the tenth transistor M10. In this case, the ninth transistor M9 and the tenth transistor M10 may be output transistors that output an n^{th} emission control signal EM_n. For example, the ninth transistor M9 may be a pull-up transistor and the tenth transistor M10 may be a pull-down transistor.

A gate electrode of the first transistor M1 may be connected to the first clock line CL1 to receive a first clock signal CLK1, a drain electrode of the first transistor M1 may be connected to the carry output terminal COT_n−1 of the (n−1)^{th} stage to receive a carry output signal CR_n−1(FLM), and a source electrode of the first transistor M1 may be connected to a first set node NQ1.

A gate electrode of the second transistor M2 may be connected to the first set node NQ1, a drain electrode of the second transistor M2 may be connected to the first clock line CL1, and a source electrode of the second transistor M2 may be connected to a first reset node NQB1. Meanwhile, the second transistor M2 may include a second-first sub-transistor M2-1 and a second-second sub-transistor M2-2 connected in series between the first clock line CL1 and the first reset node NQB1.

The gate electrode of the third transistor M3 may be connected to the first clock line CL1, the drain electrode of the third transistor M3 may be connected to the gate high voltage line GHL to receive a gate high voltage VGH, and the source electrode of the third transistor M3 may be connected to the first reset node NQB1.

The gate electrode of the fourth transistor M4 may be connected to a second set node NQ2, the drain electrode of the fourth transistor M4 may be connected to a third clock line CL3 to receive a third clock signal CLK3, and the source electrode of the fourth transistor M4 may be connected to the drain electrode of the fifth transistor M5.

The gate electrode of the fifth transistor M5 may be connected to the first reset node NQB1, the drain electrode of the fifth transistor M5 may be connected to the source electrode of the fourth transistor M4, and the source electrode of the fifth transistor M5 may be connected to the first gate low voltage line GLL1.

The gate electrode of the sixth transistor M6 may be connected to a second reset node NQB2, the drain electrode of the sixth transistor M6 may be connected to the third clock line CL3, and the source electrode of the sixth transistor M6 may be connected to the drain electrode of the seventh transistor M7.

The gate electrode of the seventh transistor M7 may be connected to the third clock line CL3, the drain electrode of the seventh transistor M7 may be connected to the source electrode of the sixth transistor M6, and the source electrode of the seventh transistor M7 may be connected to a third reset node NQB3.

The gate electrode of the eighth transistor M8 may be connected to the first set node NQ1, the drain electrode of the eighth transistor M8 may be connected to the third reset node NQB3, and the source electrode of the eighth transistor M8 may be connected to the second gate low voltage line GLL2.

The gate electrode of the ninth transistor M9 may be connected to the second set node NQ2, the drain electrode of the ninth transistor M9 may be connected to the gate high voltage line GHL, and the source electrode of the ninth transistor M9 may be connected to the scan output terminal GOT_n.

The gate electrode of the tenth transistor M10 may be connected to the third reset node NQB3, the drain electrode of the tenth transistor M10 may be connected to the carry output terminal COT_n, and the source electrode of the tenth transistor M10 may be connected to the first gate low voltage line GLL1.

A gate electrode of the eleventh transistor M11 may be connected to the gate high voltage line GHL, a drain electrode of the eleventh transistor M11 may be connected to the first reset node NQB1, and a source electrode of the eleventh transistor M11 may be connected to the second reset node NQB2.

A gate electrode of the twelfth transistor M12 may be connected to the gate high voltage line GHL, a drain electrode of the twelfth transistor M12 may be connected to the first set node NQ1, and a source electrode of the twelfth transistor M12 may be connected to the second set node NQ2.

A gate electrode of the thirteenth transistor M13 may be connected to the second set node NQ2, a drain electrode of the thirteenth transistor M13 may be connected to the gate high voltage line GHL, and a source electrode of the thirteenth transistor M13 may be connected to the carry output terminal COT_n.

A gate electrode of the fourteenth transistor M14 may be connected to the third reset node NQB3, a drain electrode of the fourteenth transistor M14 may be connected to the carry output terminal COT_n, and a source electrode of the fourteenth transistor M14 may be connected to the second gate low voltage line GLL2.

A gate electrode of the fifteenth transistor M15 may be connected to a reset signal line RL, a drain electrode of the fifteenth transistor M15 may be connected to the first set node NQ1, and a source electrode of the fifteenth transistor M15 may be connected to the first gate low voltage line GLL1. Here, the reset signal line RL may transmit a reset signal ESR. The reset signal ESR may have, for example, the same level as the gate high voltage VGH. In one or more other embodiments, the reset signal ESR may be the (n+2)^{th} carry signal from the subsequent stage (e.g., (n+2)^{th} stage). The reset signal ESR may be simultaneously applied to the gate electrodes of the fifteenth transistors M15 provided in all stages of the emission driver 620, for example.

The first electrode of the first capacitor C1 may be connected to the gate high voltage line GHL, and the second electrode of the first capacitor C1 may be connected to the carry output terminal COT_n.

The first electrode of the second capacitor C2 may be connected to the third reset node NQB3, and the second electrode of the second capacitor C2 may be connected to the first gate low voltage line GLL1.

The first electrode of the third capacitor C3 may be connected to the second set node NQ2, and the second electrode of the third capacitor C3 may be connected to the source electrode of the fourth transistor M4.

The first electrode of the fourth capacitor C4 may be connected to the second reset node NQB2, and the second electrode of the fourth capacitor C4 may be connected to the source electrode of the sixth transistor M6.

The first to fifteenth transistors M1 to M15 of FIG. 7 may be formed as n-type MOS transistors or p-type MOS transistors.

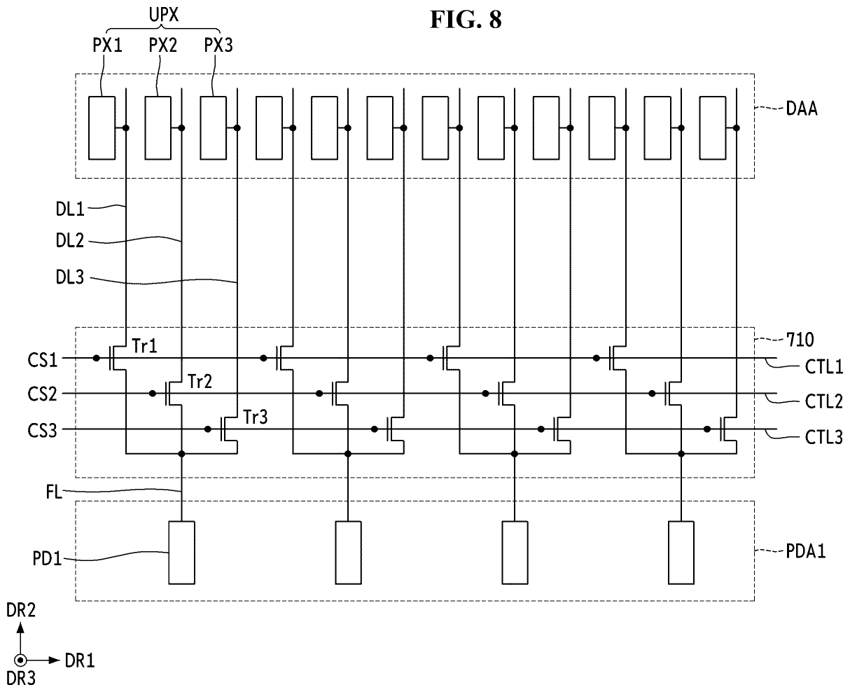

FIG. 8 is a detailed configuration diagram of the first distribution circuit 710 of FIG. 4.

As shown in FIG. 8, the first distribution circuit 710 may include a plurality of first transistors Tr1, a plurality of second transistors Tr2, and a plurality of third transistors Tr3.

The gate electrodes of the first transistors Tr1 may be commonly connected to the first control line CTL1, the gate electrodes of the second transistors Tr2 may be commonly connected to the second control line CTL2, and the gate electrodes of the third transistors Tr3 may be commonly connected to the third control line CTL3.

The drain electrode of the first transistor Tr1, the drain electrode of the second transistor Tr2, and the drain electrode of the third transistor Tr3 may be commonly connected to the first pad PD1 through a fan-out line FL.

The source electrode of the first transistor Tr1 may be connected to the first pixel PX1 through the first data line DL1. The source electrode of the second transistor Tr2 may be connected to the second pixel PX2 through the second data line DL2. The source electrode of the third transistor Tr3 may be connected to the third pixel PX3 through the third data line DL3.

The first control signal CS1, the second control signal CS2, and the third control signal CS3 may be sequentially supplied to the first control line CTL1, the second control line CTL2, and the third control line CTL3. Accordingly, the first transistor Tr1, the second transistor Tr2, and the third transistor Tr3 may be sequentially turned on. When the first control signal CS1 is applied to the first control line CTL1, the first transistors Tr1 may all be turned on, and the first data voltage applied to each first pad PD1 may be applied to each first data line DL1 through each fan-out line FL and each turned-on first transistor Tr1. When the second control signal CS2 is applied to the second control line CTL2, the second transistors Tr2 may all be turned on, and the second data voltage applied to each first pad PD1 may be applied to each second data line DL2 through each fan-out line FL and each turned-on second transistor Tr2. When the third control signal CS3 is applied to the third control line CTL3, the third transistors Tr3 may all be turned on, and the third data voltage applied to each first pad PD1 may be applied to each third data line DL3 through each fan-out line FL and each turned-on third transistor Tr3.

The first to third transistors Tr1 to Tr3 of FIG. 8 may be formed as n-type MOS transistors or p-type MOS transistors.

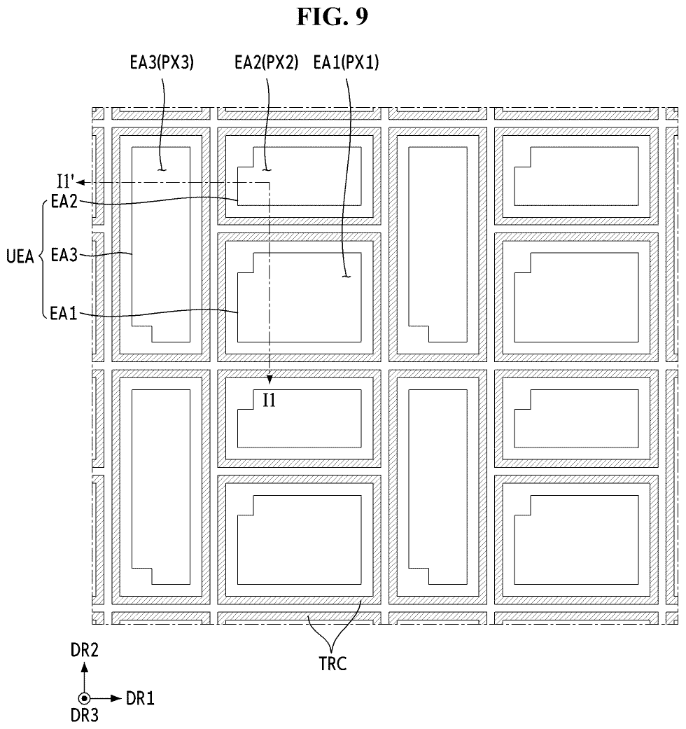

FIGS. 9 and 10 are layout diagrams illustrating embodiments of the display area of FIG. 4.

Referring to FIGS. 9 and 10, each of the plurality of unit pixels UPX includes a first emission area EA1 as an emission area of the first pixel PX1, a second emission area EA2 as an emission area of the second pixel PX2, and a third emission area EA3 as an emission area of the third pixel PX3. In other words, the unit pixel UPX may include a unit emission area UEA, and the unit emission area UEA includes the first emission area EA1, the second emission area EA2, and the third emission area EA3 described above.

Referring to FIGS. 9 and 10, each of the plurality of pixels PX includes the first emission area EA1 as an emission area of the first pixel PX1, the second emission area EA2 as an emission area of the second pixel PX2, and the third emission area EA3 as an emission area of the third pixel PX3.

Each of the first emission area EA1, the second emission area EA2, and the third emission area EA3 may have a polygonal, circular, elliptical, or atypical shape in plan view.

The maximum length of the third emission area EA3 in the first direction DR1 may be less than the maximum length of the second emission area EA2 in the first direction DR1 and the maximum length of the first emission area EA1 in the first direction DR1. The maximum length of the second emission area EA2 in the first direction DR1 and the maximum length of the first emission area EA1 in the first direction DR1 may be substantially the same.

The maximum length of the third emission area EA3 in the second direction DR2 may be greater than the maximum length of the second emission area EA2 in the second direction DR2 and the maximum length of the first emission area EA1 in the second direction DR2. The maximum length of the third emission area EA3 in the second direction DR2 may be greater than the maximum length of the first emission area EA1 in the second direction DR2. The maximum length of the first emission area EA1 in the second direction DR2 may be greater than the maximum length of the second emission area EA2 in the second direction DR2.

The first emission area EA1, the second emission area EA2, and the third emission area EA3 may have, in plan view, a hexagonal shape formed of six straight lines as shown in FIGS. 9 and 10, but the present disclosure is not limited thereto. The first emission area EA1, the second emission area EA2, and the third emission area EA3 may have a polygonal shape other than a hexagon, a circular shape, an elliptical shape, or an atypical shape in plan view.

As shown in FIG. 9, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different.

Alternatively, as shown in FIG. 10, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first emission area EA1 may emit light of a first color, the second emission area EA2 may emit light of a second color, and the third emission area EA3 may emit light of a third color. Here, the light of the first color may be light of a blue wavelength band, the light of the second color may be light of a green wavelength band, and the light of the third color may be light of a red wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

It is shown in FIGS. 9 and 10 that each of the plurality of pixels PX includes three emission areas EA1, EA2, and EA3, but the present disclosure is not limited thereto. That is, each of the plurality of pixels PX may include four emission areas.

In addition, the layout of the emission areas of the plurality of pixels PX is not limited to those illustrated in FIGS. 9 and 10. For example, the emission areas of the plurality of pixels PX may be located in a stripe structure in which the emission areas are arranged in the first direction DR1, a PenTile® structure (PenTile® being a registered trademark of Samsung Display Co., Ltd., Republic of Korea) in which the emission areas are arranged in a diamond shape, or a hexagonal structure in which the emission areas having, in plan view, a hexagonal shape are arranged as shown in FIG. 10.

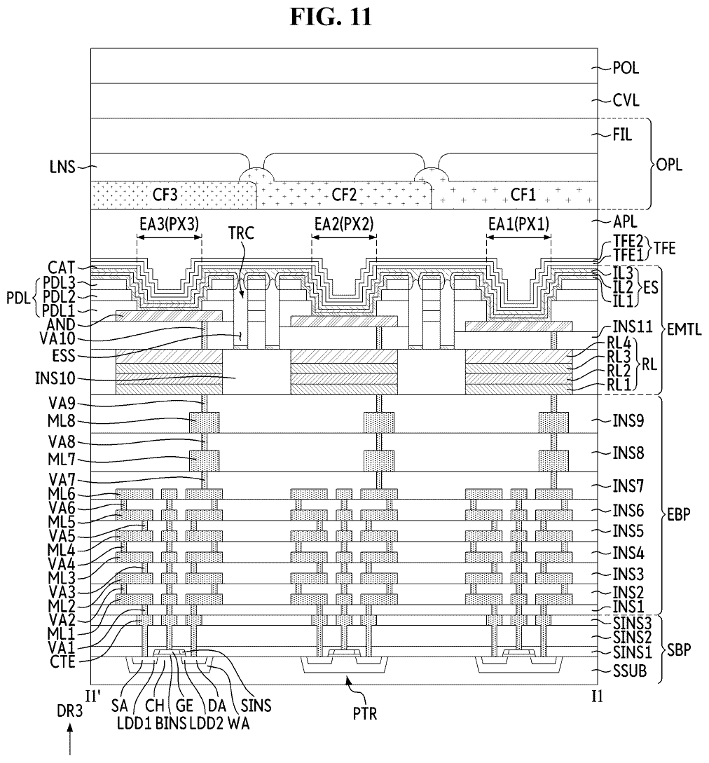

FIG. 11 is a cross-sectional view illustrating an example of the display panel 100 taken along the line 11-11′ of FIG. 9.

Referring to FIG. 11, the display panel 100 includes a semiconductor backplane SBP, a light-emitting element backplane EBP, a display element layer EMTL, an encapsulation layer TFE, an optical layer OPL, a cover layer CVL, and a polarizing plate POL.

The semiconductor backplane SBP may include the semiconductor substrate SSUB including a plurality of pixel transistors PTR, a plurality of semiconductor insulating layers covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3. The plurality of pixel transistors may be formed as n-type MOS transistors or p-type MOS transistors.

The semiconductor substrate SSUB may be a silicon substrate, a germanium substrate, or a silicon-germanium substrate. The semiconductor substrate SSUB may be a substrate doped with a first type impurity. A plurality of well regions WA may be located on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH located between the source region SA and the drain region DA.

A lower insulating film BINS may be located between a gate electrode GE and the well region WA. A side insulating film SINS may be located on the side surface of the gate electrode GE. The side insulating film SINS may be located on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be located on one side of the gate electrode GE, and the drain region DA may be located on the other side of the gate electrode GE.

Each of the plurality of well regions WA further includes a first low-concentration impurity region LDD1 located between the channel region CH and the source region SA, and a second low-concentration impurity region LDD2 located between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be reduced or prevented.

A first semiconductor insulating film SINS1 may be located on the semiconductor substrate SSUB. The first semiconductor insulating film SINS1 may be formed of silicon carbonitride (SiCN) or a silicon oxide (SiOx)-based inorganic film, but the present disclosure is not limited thereto.

A second semiconductor insulating film SINS2 may be located on the first semiconductor insulating film SINS1. The second semiconductor insulating film SINS2 may be formed of a silicon oxide (SiOx)-based inorganic film, but the present disclosure is not limited thereto.

The plurality of contact terminals CTE may be located on the second semiconductor insulating film SINS2. Each of the plurality of contact terminals CTE may be connected to any one of the gate electrode GE, the source region SA, or the drain region DA of each of the pixel transistors PTR through a hole penetrating the first semiconductor insulating film SINS1 and the second semiconductor insulating film INS2. The plurality of contact terminals CTE may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them.

A third semiconductor insulating film SINS3 may be located on a side surface of each of the plurality of contact terminals CTE. The top surface of each of the plurality of contact terminals CTE may be exposed without being covered by the third semiconductor insulating film SINS3. The third semiconductor insulating film SINS3 may be formed of a silicon oxide (SiOx)-based inorganic film, but the present disclosure is not limited thereto.

The semiconductor substrate SSUB may be replaced with a glass substrate or a polymer resin substrate, such as polyimide. In this case, thin film transistors may be located on the glass substrate or the polymer resin substrate. The glass substrate may be a rigid substrate that does not bend, and the polymer resin substrate may be a flexible substrate that can be bent or curved.

The light-emitting element backplane EBP includes a plurality of conductive layers ML1 to ML8, a plurality of vias VA1 to VA9, and a plurality of insulating films INS1 to INS9. In addition, the light-emitting element backplane EBP includes a plurality of insulating films INS1 to INS11 located between the first to eighth conductive layers ML1 to ML8.

The first to eighth conductive layers ML1 to ML8 serve to connect the plurality of contact terminals CTE exposed from the semiconductor backplane SBP to thereby implement the circuit of the first pixel PX1 shown in FIG. 3. For example, the first to sixth transistors T1 to T6 are merely formed on the semiconductor backplane SBP, and the connection of the first to sixth transistors T1 to T6 and the first and second capacitors C1 and C2 is accomplished through the first to eighth conductive layers ML1 to ML8. In addition, the connection between the drain region corresponding to the drain electrode of the fourth transistor T4, the source region corresponding to the source electrode of the fifth transistor T5, and the first electrode of the light-emitting element LE is also accomplished through the first to eighth conductive layers ML1 to ML8.

The first insulating film INS1 may be located on the semiconductor backplane SBP. Each of the first vias VA1 may penetrate the first insulating film INS1, and may be connected to the contact terminal CTE exposed from the semiconductor backplane SBP. Each of the first conductive layers ML1 may be located on the first insulating film INS1 and may be connected to the first via VA1.

The second insulating film INS2 may be located on the first insulating film INS1 and the first conductive layers ML1. Each of the second vias VA2 may penetrate the second insulating film INS2, and may be connected to the exposed first conductive layer ML1. Each of the second conductive layers ML2 may be located on the second insulating film INS2 and may be connected to the second via VA2.

The third insulating film INS3 may be located on the second insulating film INS2 and the second conductive layers ML2. Each of the third vias VA3 may penetrate the third insulating film INS3, and may be connected to the exposed second conductive layer ML2. Each of the third conductive layers ML3 may be located on the third insulating film INS3 and may be connected to the third via VA3.

A fourth insulating film INS4 may be located on the third insulating film INS3 and the third conductive layers ML3. Each of the fourth vias VA4 may penetrate the fourth insulating film INS4, and may be connected to the exposed third conductive layer ML3. Each of the fourth conductive layers ML4 may be located on the fourth insulating film INS4 and may be connected to the fourth via VA4.

A fifth insulating film INS5 may be located on the fourth insulating film INS4 and the fourth conductive layers ML4. Each of the fifth vias VA5 may penetrate the fifth insulating film INS5, and may be connected to the exposed fourth conductive layer ML4. Each of the fifth conductive layers ML5 may be located on the fifth insulating film INS5 and may be connected to the fifth via VA5.

A sixth insulating film INS6 may be located on the fifth insulating film INS5 and the fifth conductive layers ML5. Each of the sixth vias VA6 may penetrate the sixth insulating film INS6, and may be connected to the exposed fifth conductive layer ML5. Each of the sixth conductive layers ML6 may be located on the sixth insulating film INS6 and may be connected to the sixth via VA6.

A seventh insulating film INS7 may be located on the sixth insulating film INS6 and the sixth conductive layers ML6. Each of the seventh vias VA7 may penetrate the seventh insulating film INS7, and may be connected to the exposed sixth conductive layer ML6. Each of the seventh conductive layers ML7 may be located on the seventh insulating film INS7 and may be connected to the seventh via VA7.

An eighth insulating film INS8 may be located on the seventh insulating film INS7 and the seventh conductive layers ML7. Each of the eighth vias VA8 may penetrate the eighth insulating film INS8, and may be connected to the exposed seventh conductive layer ML7. Each of the eighth conductive layers ML8 may be located on the eighth insulating film INS8 and may be connected to the eighth via VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The first to eighth vias VA1 to VA8 may be made of substantially the same material. First to eighth insulating films INS1 to INS8 may be formed of a silicon oxide (SiOx)-based inorganic film, but the present disclosure is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å. The thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9000 Å. The thickness of each of the seventh via VA7 and the eighth via VA8 may be approximately 6000 Å.

A ninth insulating film INS9 may be located on the eighth insulating film INS8 and the eighth conductive layer ML8. The ninth insulating film INS9 may be formed of a silicon oxide (SiOx)-based inorganic film, but the present disclosure is not limited thereto.

Each of the ninth vias VA9 may penetrate the ninth insulating film INS9, and may be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The thickness of the ninth via VA9 may be approximately 16500 Å.

The display element layer EMTL may be located on the light-emitting element backplane EBP. The display element layer EMTL may include the light-emitting elements LE each including a reflective electrode layer RL, tenth and eleventh insulating films INS10 and INS11, a tenth via VA10, a first electrode AND, a light-emitting stack ES, and a second electrode CAT. The display element layer EMTL may also include a pixel-defining film PDL, and a plurality of trenches TRC.

The reflective electrode layer RL may be located on the ninth insulating film INS9. The reflective electrode layer RL may include at least one reflective electrode RL1, RL2, RL3, and RL4. For example, the reflective electrode layer RL may include first to fourth reflective electrodes RL1, RL2, RL3, and RL4 as shown in FIG. 11.

Each of the first reflective electrodes RL1 may be located on the ninth insulating film INS9, and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the first reflective electrodes RL1 may include titanium nitride (TiN).

Each of the second reflective electrodes RL2 may be located on a corresponding first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the second reflective electrodes RL2 may include aluminum (Al).

Each of the third reflective electrodes RL3 may be located on a corresponding second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the third reflective electrodes RL3 may include titanium nitride (TiN).

Each of the fourth reflective electrodes RL4 may be located on a corresponding third reflective electrode RL3. The fourth reflective electrodes RL4 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the fourth reflective electrodes RL4 may include titanium (Ti).

Because the second reflective electrode RL2 is an electrode that substantially reflects light from the light-emitting elements LE, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be approximately 100 Å, and the thickness of the second reflective electrode RL2 may be approximately 850 Å.

The tenth insulating film INS10 may be located on the ninth insulating film INS9. The tenth insulating film INS10 may be located between the reflective electrode layers RL adjacent to each other in a horizontal direction. The tenth insulating film INS10 may be located on the reflective electrode layer RL in the third pixel PX3, in one or more embodiments. The tenth insulating film INS10 may be formed of a silicon oxide (SiOx)-based inorganic film, but the present disclosure is not limited thereto.

The eleventh insulating film INS11 may be located on the tenth insulating film INS10 and the reflective electrode layer RL. The eleventh insulating film INS11 may be formed of a silicon oxide (SiOx)-based inorganic film, but the present disclosure is not limited thereto. The tenth insulating film INS10 and the eleventh insulating film INS11 may be an optical auxiliary layer through which light reflected by the reflective electrode layer RL passes, among light emitted from the light-emitting elements LE.

To match the resonance distance of the light emitted from the light-emitting elements LE in at least one of the first pixel PX1, the second pixel PX2, or the third pixel PX3, the tenth insulating film INS10, and the eleventh insulating film INS11 may not be located under the first electrode AND of the first pixel PX1. The first electrode AND of the first pixel PX1 may be directly located on the reflective electrode layer RL. The eleventh insulating film INS11 may be located under the first electrode AND of the second pixel PX2. The tenth insulating film INS10 and the eleventh insulating film INS11 may be located under the first electrode AND of the third pixel PX3.

In summary, the distance between the first electrode AND and the reflective electrode layer RL may be different in the first pixel PX1, the second pixel PX2, and the third pixel PX3. To adjust the distance from the reflective electrode layer RL to the second electrode CAT according to the main wavelength of the light emitted from each of the first pixel PX1, the second pixel PX2, and the third pixel PX3, the presence or absence of the tenth insulating film INS10 and the eleventh insulating film INS11 may be set in each of the first pixel PX1, the second pixel PX2, and the third pixel PX3. For example, it is illustrated in FIG. 11 that the distance between the first electrode AND and the reflective electrode layer RL in the third pixel PX3 is greater than the distance between the first electrode AND and the reflective electrode layer RL in the second pixel PX2 and the distance between the first electrode AND and the reflective electrode layer RL in the first pixel PX1. It is also shown in FIG. 11 that the distance between the first electrode AND and the reflective electrode layer RL in the second pixel PX2 is greater than the distance between the first electrode AND and the reflective electrode layer RL in the first pixel PX1. However, the present disclosure is not limited thereto.

In addition, although the tenth insulating film INS10 and the eleventh insulating film INS11 are illustrated in the present disclosure, a twelfth insulating film located under the first electrode AND of the first pixel PX1 may be added in one or more embodiments. In this case, the eleventh insulating film INS11 and the twelfth insulating film may be located under the first electrode AND of the second pixel PX2, and the tenth insulating film INS10, the eleventh insulating film INS11, and the twelfth insulating film may be located under the first electrode AND of the third pixel PX3.

Each of the tenth vias VA10 may penetrate the tenth insulating film INS10 and/or the eleventh insulating film INS11 in the second pixel PX2 and the third pixel PX3 and may be connected to the exposed reflective electrode layer RL. The tenth vias VA10 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The thickness of the tenth via VA10 in the second pixel PX2 may be less than the thickness of the tenth via VA10 in the third pixel PX3.

The first electrode AND of each of the light-emitting elements LE may be located on the tenth insulating film INS10 and connected to the tenth via VA10. The first electrode AND of each of the light-emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE.

The first electrode AND of each of the light-emitting elements LE may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the first electrode AND of each of the light-emitting elements LE may be titanium nitride (TiN).

The pixel-defining film PDL may be located on a part of the first electrode AND of each of the light-emitting elements LE. The pixel-defining film PDL may cover the edge of the first electrode AND of each of the light-emitting elements LE. The pixel-defining film PDL may serve to partition the first emission areas EA1, the second emission areas EA2, and the third emission areas EA3.

The first emission area EA1 may be defined as an area in which the first electrode AND, the light-emitting stack ES, and the second electrode CAT are sequentially stacked in the first pixel PX1 to emit light. The second emission area EA2 may be defined as an area in which the first electrode AND, the light-emitting stack ES, and the second electrode CAT are sequentially stacked in the second pixel PX2 to emit light. The third emission area EA3 may be defined as an area in which the first electrode AND, the light-emitting stack ES, and the second electrode CAT are sequentially stacked in the third pixel PX3 to emit light.

The pixel-defining film PDL may include first to third pixel-defining films PDL1, PDL2, and PDL3. The first pixel-defining film PDL1 may be located on the edge of the first electrode AND of each of the light-emitting elements LE, the second pixel-defining film PDL2 may be located on the first pixel-defining film PDL1, and the third pixel-defining film PDL3 may be located on the second pixel-defining film PDL2. The first pixel-defining film PDL1, the second pixel-defining film PDL2, and the third pixel-defining film PDL3 may be formed of a silicon oxide (SiOx)-based inorganic film, but the present disclosure is not limited thereto. The first pixel-defining film PDL1, the second pixel-defining film PDL2, and the third pixel-defining film PDL3 may each have a thickness of about 500 Å.

When the first pixel-defining film PDL1, the second pixel-defining film PDL2, and the third pixel-defining film PDL3 are formed as one pixel-defining film, the height of the one pixel-defining film increases, so that a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, to reduce or prevent the likelihood of the first encapsulation inorganic film TFE1 being cut off due to the step coverage, the first pixel-defining film PDL1, the second pixel-defining film PDL2, and the third pixel-defining film PDL3 may have a cross-sectional structure having a stepped portion. For example, the width of the first pixel-defining film PDL1 may be greater than the width of the second pixel-defining film PDL2 and the width of the third pixel-defining film PDL3. Also, the width of the second pixel-defining film PDL2 may be greater than the width of the third pixel-defining film PDL3. The width of the first pixel-defining film PDL1 refers to the horizontal length of the first pixel-defining film PDL1 defined in the first direction DR1 and the second direction DR2.

Each of the plurality of trenches TRC may penetrate the first pixel-defining film PDL1, the second pixel-defining film PDL2, and the third pixel-defining film PDL3. Furthermore, each of the plurality of trenches TRC may penetrate the eleventh insulating film INS11. The tenth insulating film INS10 may be partially recessed at each of the plurality of trenches TRC.

At least one trench TRC may be located between the neighboring pixels PX1, PX2, and PX3. Although FIG. 11 illustrates that two trenches TRC are located between the neighboring pixels PX1, PX2, and PX3, the present disclosure is not limited thereto.

The light-emitting stack ES may include a plurality of stack layers. FIG. 11 illustrates that the light-emitting stack ES has a three-tandem structure including a first stack layer IL1, a second stack layer IL2, and a third stack layer IL3, but the present disclosure is not limited thereto. For example, the light-emitting stack ES may have a two-tandem structure including two intermediate layers.

In the three-tandem structure, the light-emitting stack ES may have a tandem structure including a plurality of stack layers IL1, IL2, and IL3 that emit different lights. For example, the light-emitting stack ES may include the first stack layer IL1 that emits light of the first color, the second stack layer IL2 that emits light of the third color, and the third stack layer IL3 that emits light of the second color. The first stack layer IL1, the second stack layer IL2, and the third stack layer IL3 may be sequentially stacked.

The first stack layer IL1 may have a structure in which a first hole transport layer, a first organic light-emitting layer that emits light of the first color, and a first electron transport layer are sequentially stacked. The second stack layer IL2 may have a structure in which a second hole transport layer, a second organic light-emitting layer that emits light of the third color, and a second electron transport layer are sequentially stacked. The third stack layer IL3 may have a structure in which a third hole transport layer, a third organic light-emitting layer that emits light of the second color, and a third electron transport layer are sequentially stacked.

A first charge generation layer for supplying charges to the second stack layer IL2 and for supplying electrons to the first stack layer IL1 may be located between the first stack layer IL1 and the second stack layer IL2. The first charge generation layer may include an N-type charge generation layer that supplies electrons to the first stack layer IL1, and a P-type charge generation layer that supplies holes to the second stack layer IL2. The N-type charge generation layer may include a dopant of a metal material.

A second charge generation layer for supplying charges to the third stack layer IL3 and for supplying electrons to the second stack layer IL2 may be located between the second stack layer IL2 and the third stack layer IL3. The second charge generation layer may include an N-type charge generation layer that supplies electrons to the second stack layer IL2, and a P-type charge generation layer that supplies holes to the third stack layer IL3.

The first stack layer IL1 may be located on the first electrodes AND and the pixel-defining film PDL, and may be located on the bottom surface of each trench TRC. Due to the trench TRC, the first stack layer IL1 may be cut off between the neighboring pixels PX1, PX2, and PX3. The second stack layer IL2 may be located on the first stack layer IL1. Due to the trench TRC, the second stack layer IL2 may be cut off between the neighboring pixels PX1, PX2, and PX3. A cavity ESS or an empty space may be located between the first stack layer IL1 and the second stack layer IL2. The third stack layer IL3 may be located on the second stack layer IL2. The third stack layer IL3 is not cut off by the trench TRC, and may cover the second stack layer IL2 in each of the trenches TRC. That is, in the three-tandem structure, each of the plurality of trenches TRC may be a structure for cutting off the first to second stack layers IL1 and IL2, the first charge generation layer, and the second charge generation layer of the display element layer EMTL between the neighboring pixels PX1, PX2, and PX3. In addition, in the two-tandem structure, each of the trenches TRC may be a structure for cutting off the charge generation layer located between a lower intermediate layer and an upper intermediate layer, and the lower intermediate layer.

To stably cut off the first and second stack layers IL1 and IL2 of the display element layer EMTL between the neighboring pixels PX1, PX2, and PX3, the height of each of the plurality of trenches TRC may be greater than the height of the pixel-defining film PDL. The height of each of the plurality of trenches TRC refers to the length of each of the plurality of trenches TRC in the third direction DR3. The height of the pixel-defining film PDL refers to the length of the pixel-defining film PDL in the third direction DR3. To cut off the first to third stack layers IL1, IL2, and IL3 of the display element layer EMTL between the neighboring pixels PX1, PX2, and PX3, another structure may exist instead of the trench TRC. For example, instead of the trench TRC, a reverse tapered partition wall may be located on the pixel-defining film PDL.

The number of the stack layers IL1, IL2, and IL3 that emit different lights is not limited to that shown in FIG. 11. For example, the light-emitting stack ES may include two intermediate layers. In this case, one of the two intermediate layers may be substantially the same as the first stack layer IL1, and the other may include a second hole transport layer, a second organic light-emitting layer, a third organic light-emitting layer, and a second electron transport layer. In this case, a charge generation layer for supplying electrons to one intermediate layer and for supplying charges to the other intermediate layer may be located between the two intermediate layers.

In addition, FIG. 11 illustrates that the first to third stack layers IL1, IL2, and IL3 are all located in the first emission area EA1, the second emission area EA2, and the third emission area EA3, but the present disclosure is not limited thereto. For example, the first stack layer IL1 may be located in the first emission area EA1, and may be omitted from the second emission area EA2 and the third emission area EA3. Furthermore, the second stack layer IL2 may be located in the second emission area EA2, and may be omitted from the first emission area EA1 and the third emission area EA3. Further, the third stack layer IL3 may be located in the third emission area EA3, and may be omitted from the first emission area EA1 and the second emission area EA2. In this case, first to third color filters CF1, CF2, and CF3 of the optical layer OPL may be omitted.

The second electrode CAT may be located on the third stack layer IL3. The second electrode CAT may be located on the third stack layer IL3 in each of the plurality of trenches TRC. The second electrode CAT may be formed of a transparent conductive material (TCO), such as ITO or IZO that can transmit light or a semi-transmissive conductive material, such as magnesium (Mg), silver (Ag), or an alloy of Mg and Ag. When the second electrode CAT is formed of a semi-transmissive conductive material, the light emission efficiency may be improved in each of the first to third pixels PX1, PX2, and PX3 due to a micro-cavity effect.

The encapsulation layer TFE may be located on the display element layer EMTL. The encapsulation layer TFE may include at least one inorganic film TFE1 and TFE2 to reduce or prevent oxygen or moisture from permeating into the display element layer EMTL. For example, the encapsulation layer TFE may include the first encapsulation inorganic film TFE1, and a second encapsulation inorganic film TFE2.

The first encapsulation inorganic film TFE1 may be located on the second electrode CAT. The first encapsulation inorganic film TFE1 may be formed as a multilayer in which one or more inorganic films selected from silicon nitride (SiNx), silicon oxy nitride (SiON), and silicon oxide (SiOx) are alternately stacked. The first encapsulation inorganic film TFE1 may be formed by a chemical vapor deposition (CVD) process.

The second encapsulation inorganic film TFE2 may be located on the first encapsulation inorganic film TFE1. The second encapsulation inorganic film TFE2 may be formed of titanium oxide (TiOx) or aluminum oxide (AlOx), but the present disclosure is not limited thereto. The second encapsulation inorganic film TFE2 may be formed by an atomic layer deposition (ALD) process. The thickness of the second encapsulation inorganic film TFE2 may be less than the thickness of the first encapsulation inorganic film TFE1.

An organic film APL may be a layer for increasing the interfacial adhesion between the encapsulation layer TFE and the optical layer OPL. The organic film APL may be an organic film, such as acrylic resin, epoxy resin, phenolic resin, polyamide resin, or polyimide resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be located on the organic film APL.

The first color filter CF1 may overlap the first emission area EA1 of the first pixel PX1. The first color filter CF1 may transmit light of the first color (e.g., light of a blue wavelength band). The blue wavelength band may be about 370 nm to about 460 nm. Thus, the first color filter CF1 may transmit light of the first color among light emitted from the first emission area EA1.

The second color filter CF2 may overlap the second emission area EA2 of the second pixel PX2. The second color filter CF2 may transmit light of the second color (e.g., light of a green wavelength band). The green wavelength band may be about 480 nm to about 560 nm. Thus, the second color filter CF2 may transmit light of the second color among light emitted from the second emission area EA2.

The third color filter CF3 may overlap the third emission area EA3 of the third pixel PX3. The third color filter CF3 may transmit light of the third color (e.g., light of a red wavelength band). The red wavelength band may be about 600 nm to about 750 nm. Thus, the third color filter CF3 may transmit light of the third color among light emitted from the third emission area EA3.

The plurality of lenses LNS may be located on the first color filter CF1, the second color filter CF2, and the third color filter CF3, respectively. Each of the plurality of lenses LNS may be a structure for increasing a ratio of light directed to the front of the display device 10. Each of the plurality of lenses LNS may have a cross-sectional shape that is convex in an upward direction.

The filling layer FIL may be located on the plurality of lenses LNS. The filling layer FIL may have a refractive index (e.g., predetermined refractive index) such that light travels in the third direction DR3 at an interface between the filling layer FIL and the plurality of lenses LNS. Further, the filling layer FIL may be a planarization layer. The filling layer FIL may be an organic film, such as acrylic resin, epoxy resin, phenolic resin, polyamide resin, or polyimide resin.

The cover layer CVL may be located on the filling layer FIL. The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate POL may be located on one surface of the cover layer CVL. The polarizing plate POL may be a structure for reducing or preventing visibility degradation caused by reflection of external light. The polarizing plate POL may include a linear polarizing plate and a phase retardation film. For example, the phase retardation film may be a/4 plate (quarter-wave plate), but the present disclosure is not limited thereto. However, when visibility degradation caused by reflection of external light is sufficiently overcome by the first to third color filters CF1, CF2, and CF3, the polarizing plate POL may be omitted.

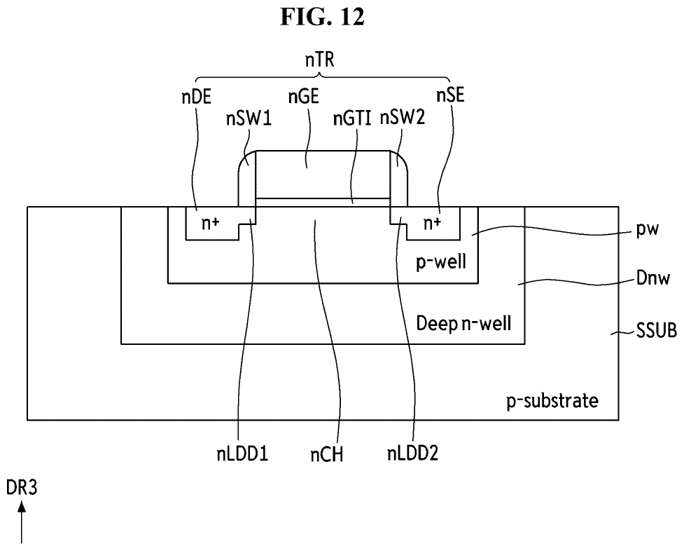

FIG. 12 is a cross-sectional view of an n-type MOS transistor.

An n-type transistor nTR (hereinafter, referred to as an n-type MOS transistor) may include a gate electrode nGE, a drain electrode nDE, and a source electrode nSE.

The n-type MOS transistor nTR may be formed on the semiconductor substrate SSUB. The n-type MOS transistor nTR may be a high breakdown voltage transistor. For example, the n-type MOS transistor nTR having the structure shown in FIG. 12 may be a high breakdown voltage transistor that may withstand a breakdown voltage of about 8V or about 10V.

As shown in FIG. 12, the semiconductor substrate SSUB may be a silicon substrate, a germanium substrate, or a silicon-germanium substrate. The semiconductor substrate SSUB may be, for example, a substrate doped with a p-type impurity. In other words, the semiconductor substrate SSUB may be a p-type semiconductor substrate.

A deep-n-well region Dnw and a p-well region pw (or pocket p-well region) may be located on the semiconductor substrate SSUB. The deep-n-well region Dnw may be a region doped with an n-type impurity, and the p-well region pw may be a region doped with a p-type impurity.

The p-well region pw may surround the source electrode nSE and the drain electrode nDE.

The deep-n-well region Dnw may surround the p-well region pw.

A first low-concentration impurity region nLDD1 overlapping a first sidewall nSW1 may be located between a channel region nCH and the drain electrode nDE of the n-type MOS transistor nTR.

A second low-concentration impurity region nLDD2 overlapping a second sidewall nSW2 may be located between the channel region nCH and the source electrode nSE of the n-type MOS transistor nTR.

The gate electrode nGE of the n-type MOS transistor nTR may be located on the channel region nCH.

A gate-insulating layer nGTI may be located between the channel region nCH and the gate electrode nGE of the n-type MOS transistor nTR.

The first sidewall nSW1 may be located on the first low-concentration impurity region nLDD1.

The second sidewall nSW2 may be located on the second low-concentration impurity region nLDD2.

The first sidewall nSW1 and the second sidewall nSW2 may surround the gate-insulating layer nGTI and the gate electrode nGE in plan view.

The aforementioned pixel transistor PTR, scan transistor, light-emitting transistor, first distribution transistor, and second distribution transistor may each be formed as the n-type MOS transistor nTR, as shown in FIG. 12.

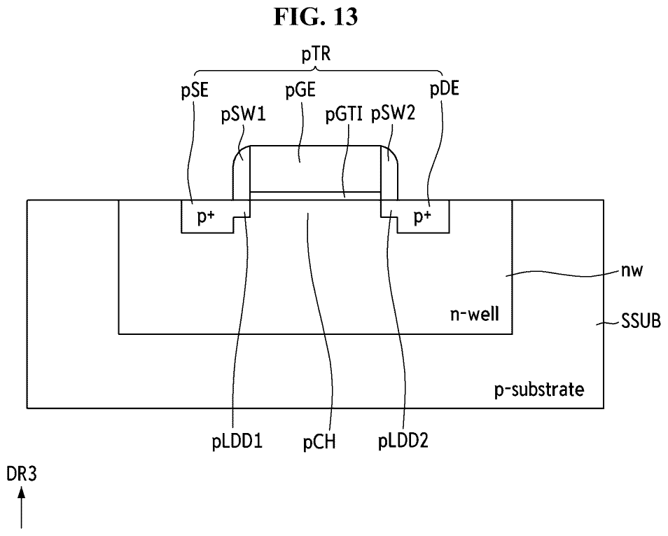

FIG. 13 is a cross-sectional view of a p-type MOS transistor pTR.

A p-type transistor pTR (hereinafter, referred to as a p-type MOS transistor) may include a gate electrode pGE, a source electrode pSE, and a drain electrode pDE.

The p-type MOS transistor pTR may be formed on a semiconductor substrate. The p-type MOS transistor pTR may be a high breakdown voltage transistor. For example, the p-type MOS transistor pTR having the structure shown in FIG. 13 may be a high breakdown voltage transistor that may withstand a breakdown voltage of about 8V or about 10V.

As shown in FIG. 13, the semiconductor substrate SSUB may be a silicon substrate, a germanium substrate, or a silicon-germanium substrate. The semiconductor substrate SSUB may be, for example, a substrate doped with a p-type impurity. In other words, the semiconductor substrate SSUB may be a p-type semiconductor substrate.

An n-well region nw may be located on the semiconductor substrate SSUB. The n-well region nw may be a region doped with an n-type impurity.

The n-well region nw may surround the drain electrode pDE and the source electrode pSE.

A first low-concentration impurity region pLDD1 overlapping a first sidewall pSW1 may be located between the channel region pCH and the drain electrode pDE of the p-type MOS transistor pTR.

A second low-concentration impurity region pLDD2 overlapping a second sidewall pSW2 may be located between the source electrode pSE and the channel region pCH of the p-type MOS transistor pTR.

The gate electrode pGE of the p-type MOS transistor pTR may be located on the channel region pCH.

A gate-insulating layer pGTI may be located between the channel region pCH and the gate electrode pGE of the p-type MOS transistor pTR.

The first sidewall pSW1 may be located on the first low-concentration impurity region pLDD1.

The second sidewall pSW2 may be located on the second low-concentration impurity region pLDD2.

The first sidewall pSW1 and the second sidewall pSW2 may surround the gate-insulating layer pGTI and the gate electrode pGE in plan view.

The aforementioned pixel transistor, scan transistor, light-emitting transistor, first distribution transistor, and second distribution transistor may each be formed as the p-type MOS transistor, as shown in FIG. 13.

According to one or more embodiments, all transistors located in the display panel 100 may be single-type (e.g., any one of a p-type or a n-type) transistors. For example, the transistors of the first driving circuit 401 and the transistors of the pixel circuit PC (e.g., pixel transistors PTR) may all be formed as single-type (e.g., any one of a p-type or a n-type) transistors. For example, the scan transistor, light-emitting transistor, first distribution transistor, second distribution transistor, and pixel transistor PTR may all be the n-type MOS transistors nTR as in the example shown in FIG. 12. Alternatively, the pixel transistor, scan transistor, light-emitting transistor, first distribution transistor, second distribution transistor, and pixel transistor PTR may all be the p-type MOS transistors pTR as in the example shown in FIG. 13.

In this way, because the transistors of the display panel 100 are all formed as the same type of MOS transistors (e.g., n-type MOS transistors), it is possible to simplify the manufacturing process of the display device 10 and reduce the manufacturing cost of display device 10.

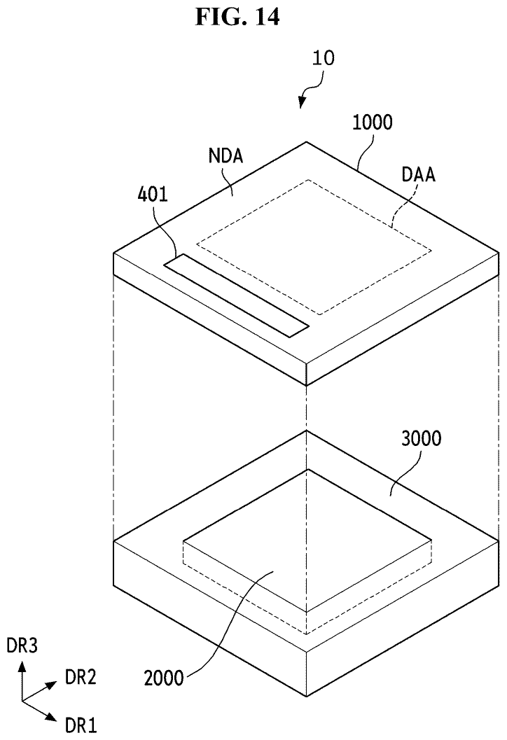

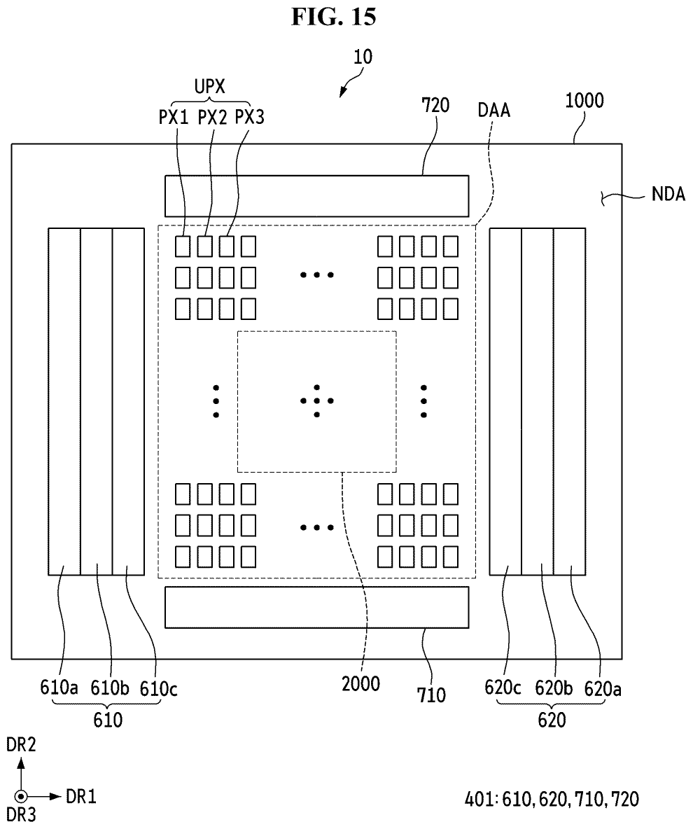

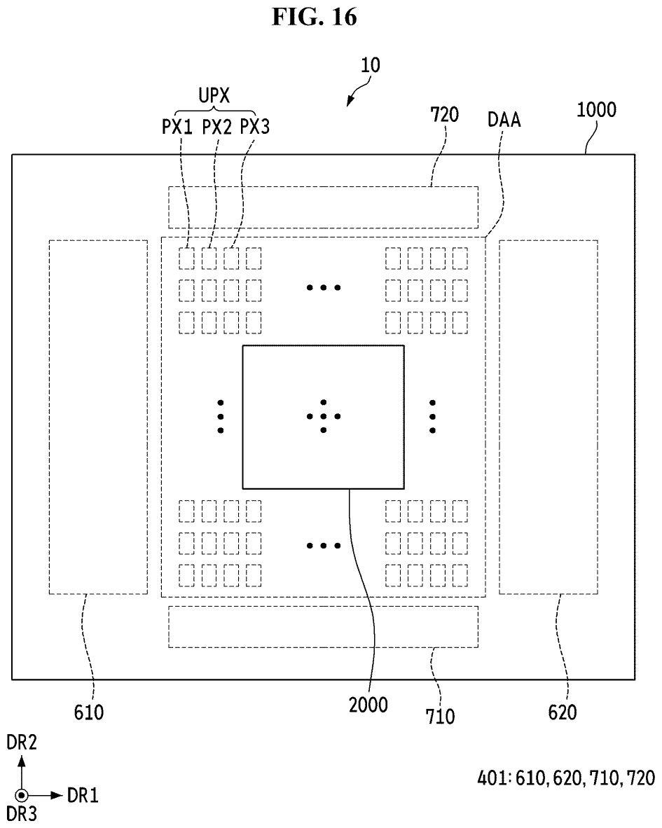

FIG. 14 is an exploded perspective view showing the display device 10 according to one or more embodiments. FIG. 15 is a plan view of the display device 10 of FIG. 14 viewed from above a display panel 1000. FIG. 16 is a plan view of the display device 10 of FIG. 14 viewed from a driver 2000.

The display device 10 according to one or more embodiments may include the display panel 1000 and the driver 2000, as shown in FIGS. 14, 15, and 16.

The display panel 1000 and the driver 2000 may face each other in the third direction DR3.

The display panel 1000 of FIG. 14 is different from the display panel 100 of FIG. 4 in that it does not include the first pad portion PDA1, the second pad portion PDA2, the third pad portion PDA3, the fourth pad portion PDA4, the fifth pad portion PDA5, and the sixth pad portion PDA6. In other words, the display panel 1000 may include the display area DAA, the non-display area NDA, the first pixel PX1, the second pixel PX2, the third pixel PX3, the scan driver 610, the emission driver 620, the first distribution circuit 710, and the second distribution circuit 720.

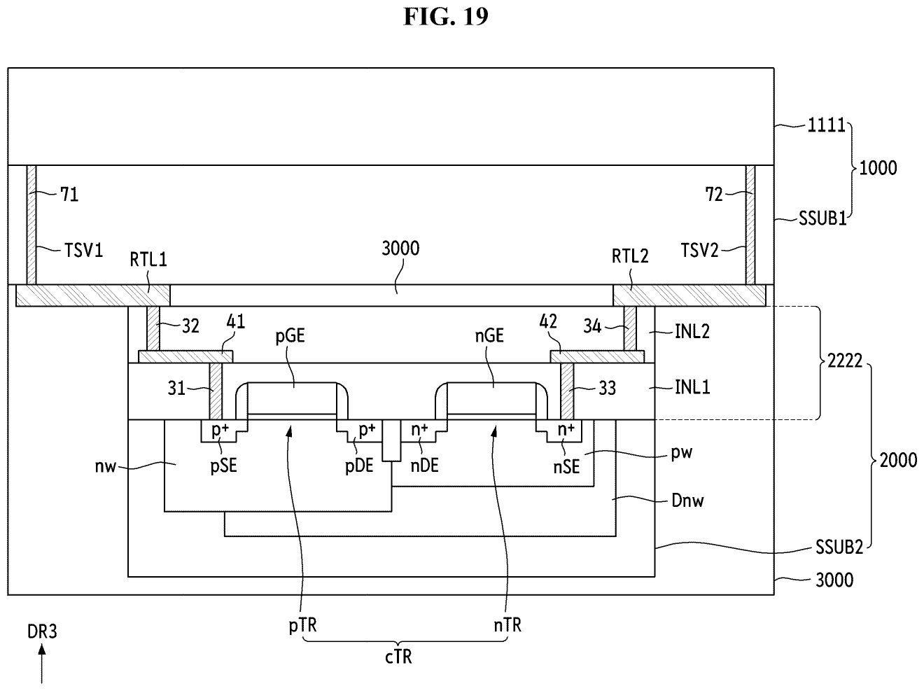

The driver 2000 may be located above the bottom surface of the display panel 1000. For example, the driver 2000 may be located above a first semiconductor substrate SSUB1 (see FIG. 19) of the display panel 1000. The driver 2000 may be located above the center of the display panel 1000. For example, the driver 2000 may be located above the center of the display panel 1000 to overlap the display area of the display panel 1000. The size of the driver 2000 may be less than the size of the display panel 1000. As shown in FIGS. 15 and 16, the edge of the driver 2000 may be surrounded by the edge of the display panel 1000 in plan view. The driver 2000 may include the aforementioned second driving circuit 402. For example, the driver 2000 may include the timing control circuit 400 and the data driver 700. Additionally, the driver 2000 may further include the power supply circuit 500 in addition to the timing control circuit 400 and the data driver 700.

A protective layer 3000 may surround the driver 2000 as shown in FIG. 14. For example, the protective layer 3000 may surround the side surfaces and the bottom surface of the driver 2000. The protective layer 3000 may be located on the driver 2000 and the display panel 1000 while surrounding the driver 2000. The protective layer 3000 may reduce a stepped portion caused by a size difference between the driver 2000 and the display panel 1000, and may also protect the driver 2000 and the display panel 1000. In addition, the protective layer 3000 may bond the driver 2000 and the display panel 1000 to each other.

The aforementioned driver 2000 may transmit various signals to the display panel 1000. To this end, the driver 2000 may be electrically connected to the display panel 1000, which will be described in detail as follows.

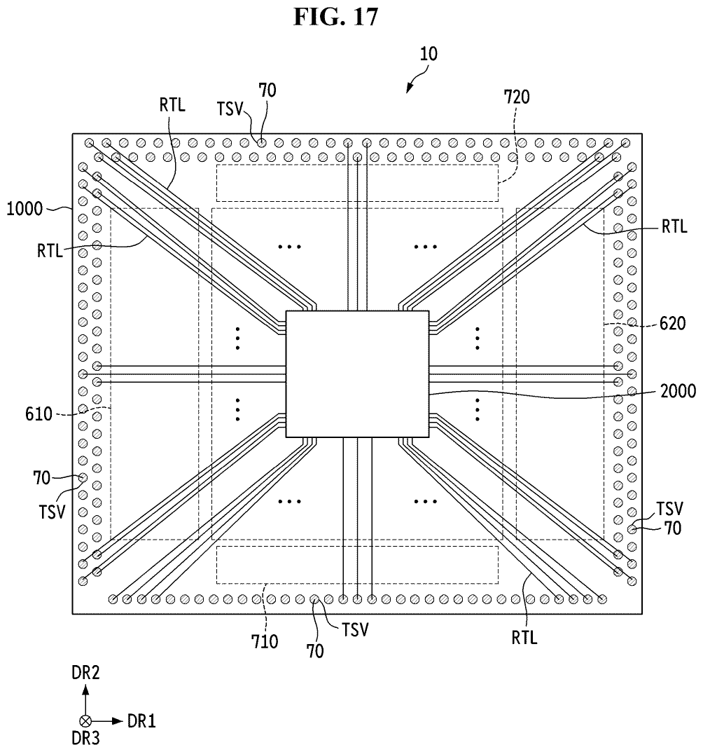

FIG. 17 is a diagram for describing electrical connection between the display panel 1000 and the driver 2000. For example, FIG. 17 may be a plan view of the display device of FIG. 14 viewed from above the driver 2000.

As described above, because the driver 2000 may be located above the bottom surface of the display panel 1000, a plurality of routing lines RTL may be located on the bottom surface of the display panel 1000. The display panel 1000 and the driver 2000 may be electrically connected to each other through the routing lines RTL. For example, the routing lines RTL may be electrically connected to the display panel 1000 via through holes TSV that penetrate the display panel 1000. The through holes TSV may penetrate, for example, the first semiconductor substrate SSUB1 (see FIG. 19) of the display panel 1000 in the third direction DR3. Because a connection electrode 70 may be located in each through hole TSV, the routing lines RTL may be electrically connected to the connection electrodes 70 of the through holes TSV, respectively. The plurality of through holes TSV and connection electrodes 70 may be located, for example, at the edge of the bottom surface of the display panel 1000. The scan-timing control signal SCS, the emission-timing control signal ECS,

the data voltages, the common voltage ELVSS, the driving voltage ELVDD, the reference voltage VREF, and the initialization voltage VINT from the driver 2000 may be supplied to the display panel 1000 through the plurality of routing lines RTL and the connection electrodes 70 in the plurality of through holes TSV.

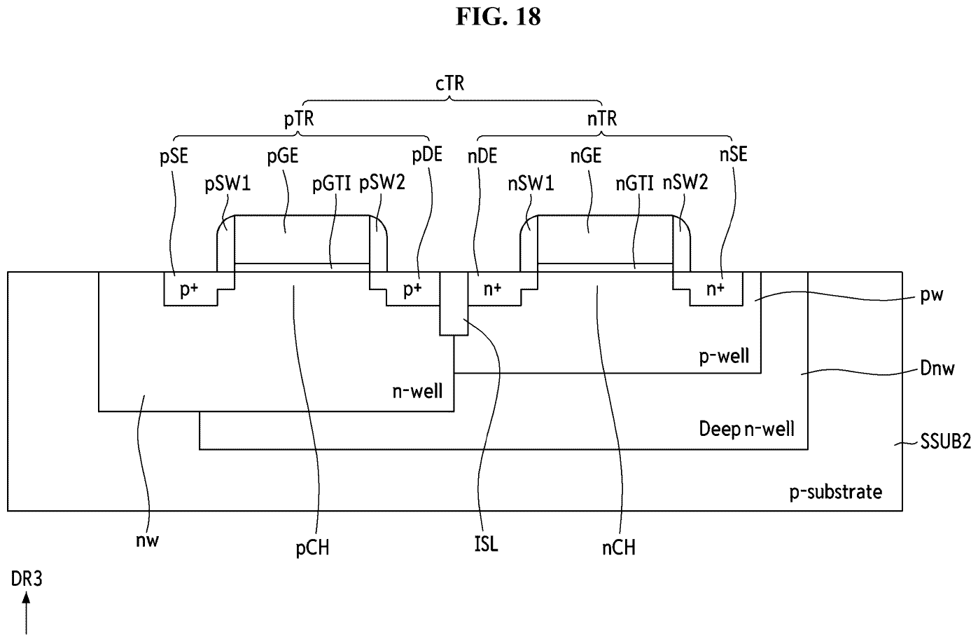

FIG. 18 is a cross-sectional view of the driver 2000 of FIG. 14.

The driver 2000 may include a second semiconductor substrate SSUB2, the n-type transistor nTR (hereinafter, referred to as an n-type MOS transistor), and the p-type transistor pTR (hereinafter, referred to as a p-type MOS transistor). For example, the driver 2000 may include a complementary metal oxide semiconductor (CMOS) transistor cTR.

The n-type MOS transistor nTR may include the gate electrode nGE, the source electrode nSE, and the drain electrode nDE located in the p-well region pw.

The p-type transistor may include the gate electrode pGE, the source electrode pSE, and the drain electrode pDE located in the n-well region nw.

The second semiconductor substrate SSUB2 may be a p-type semiconductor substrate. The deep-n-well region Dnw, the n-well region nw, the p-well region pw (or pocket p-well region), the source electrodes nSE and pSE, and the drain electrodes nDE and pDE may be located in the second semiconductor substrate SSUB2. In this case, the n-well region nw and the p-well region pw may be electrically separated from each other by an element isolation film ISL.

The second driving circuit 402 of the driver 2000 may include the CMOS transistor cTR. For example, because the timing control circuit 400 may include a plurality of timing transistors, the data driver may include a plurality of data transistors, and the power supply circuit 500 may include a plurality of power transistors, the plurality of timing transistors, the plurality of data transistors, and the plurality of power transistors described above may be formed on the second semiconductor substrate SSUB2 by a semiconductor process. For example, the plurality of timing transistors, the plurality of data transistors, and the plurality of power transistors of the second driving circuit 402 may be formed as the CMOS transistors cTR.

FIG. 19 is a cross-sectional view of the display device of FIG. 14.

As shown in FIG. 19, the display panel 1000 may include the first semiconductor substrate SSUB1 and a first driving circuit layer 1111. The first driving circuit layer 1111 may include the aforementioned first driving circuit 401 and the pixel circuit PC. For example, the first driving circuit layer 1111 may include the aforementioned pixel circuit PC, scan driver 610, emission driver 620, first distribution circuit 710, and second distribution circuit 720. In other words, the first driving circuit layer 1111 may include a pixel transistor, a scan transistor, a light-emitting transistor, a first distribution transistor, and a second distribution transistor.

All transistors of the first driving circuit layer 1111 may be formed as a single type (e.g., any one of a p-type or an n-type) transistor. For example, the pixel transistor PTR, the scan transistor, the light-emitting transistor, the first distribution transistor, and the second distribution transistor of the first driving circuit layer 1111 may all be the n-type MOS transistors nTR as in the example shown in FIG. 12. Alternatively, the pixel transistor, the scan transistor, the light-emitting transistor, the first distribution transistor, and the second distribution transistor of the first driving circuit layer 1111 may all be the p-type MOS transistors pTR as in the example shown in FIG. 13.

As shown in FIG. 19, the driver 2000 may include the second semiconductor substrate SSUB2 and a second driving circuit layer 2222. The second driving circuit layer 2222 may include the aforementioned second driving circuit 402. For example, the second driving circuit layer 2222 may include the timing control circuit 400, the data driver, and the power supply circuit 500. For example, the second driving circuit layer 2222 may include a timing transistor, a data transistor, and a power transistor.

The transistors of the second driving circuit layer 2222 may all be formed as complementary transistors. For example, the timing transistor, the data transistor, and the power transistor may all be the CMOS transistors cTR as in the example shown in FIG. 18.

In addition, the second driving circuit layer 2222 may include a first interlayer insulating layer INL1, a second interlayer insulating layer INL2, a first via 31, a first metal layer 41, a second via 32, a third via 33, a second metal layer 42, and a fourth via 34.

The first via 31 may be connected to the source electrode pSE of the p-type MOS transistor pTR through a via hole penetrating the first interlayer insulating layer INL1.

The first metal layer 41 may be located on the first interlayer insulating layer INL1. The first metal layer 41 may be connected to the first via 31, on the first interlayer insulating layer INL1.

The second via 32 may be connected to the first metal layer 41 through a via hole penetrating the second interlayer insulating layer INL2.

A first routing line RTL1 may be located on the second interlayer insulating layer INL2. The first routing line RTL1 may be connected to the second via 32, on the second interlayer insulating layer INL2. The first routing line RTL1 may extend to one edge of the first semiconductor substrate SSUB1.

A first through hole TSV1 may penetrate the first semiconductor substrate SSUB1. A first connection electrode 71 in the first through hole TSV1 may be connected to the first routing line RTL1. For example, one side of the first routing line RTL1 may be connected to the second via 32, and the other side of the first routing line RTL1 may be connected to the first connection electrode 71.

The first connection electrode 71 may be electrically connected to the components of the first driving circuit layer 1111. For example, the first connection electrode 71 may be connected to at least one of the first pixel PX1, the second pixel PX2, the third pixel PX3, the scan driver 610, the emission driver 620, the first distribution circuit 710, or the second distribution circuit 720. Accordingly, signals from the driver 2000 may be supplied to the display panel 1000.

The third via 33 may be connected to the source electrode nSE of the n-type MOS transistor nTR through a via hole penetrating the first interlayer insulating layer INL1.

The second metal layer 42 may be located on the first interlayer insulating layer INL1. The second metal layer 42 may be connected to the third via 33, on the first interlayer insulating layer INL1.

The fourth via 34 may be connected to the second metal layer 42 through a via hole penetrating the second interlayer insulating layer INL2.

A second routing line RTL2 may be located on the second interlayer insulating layer INL2. The second routing line RTL2 may be connected to the fourth via 34, on the second interlayer insulating layer INL2. The second routing line RTL2 may extend to the other edge of the first semiconductor substrate SSUB1.

A second through hole TSV2 may penetrate the first semiconductor substrate SSUB1. A second connection electrode 72 in the second through hole TSV2 may be connected to the second routing line RTL2. For example, one side of the second routing line RTL2 may be connected to the fourth via 34, and the other side of the second routing line RTL2 may be connected to the second connection electrode 72.

The second connection electrode 72 may be electrically connected to the first driving circuit 401 and the pixel circuit PC of the first driving circuit layer 1111. For example, the second connection electrode 72 may be connected to at least one of the pixel circuit PC of the first pixel PX1, the pixel circuit PC of the second pixel PX2, the pixel circuit PC of the third pixel PX3, the scan driver 610, the emission driver 620, the first distribution circuit 710, or the second distribution circuit 720. Accordingly, signals from the driver 2000 may be supplied to the display panel 1000.

According to one or more embodiments, all transistors located on the display panel 1000 may be single-type (e.g., any one of a p-type or a n-type) transistors. For example, the transistors of the first driving circuit layer 1111 may all be formed as the same type of MOS transistors (e.g., n-type MOS transistors). Accordingly, it is possible to simplify the manufacturing process of the display device 10 and reduce the manufacturing cost of the display device 10.

Meanwhile, the transistors of the driver 2000 are configured using CMOS transistors, thereby reducing the power consumption of the display device 10 and increasing the driving capability of the driver 2000.

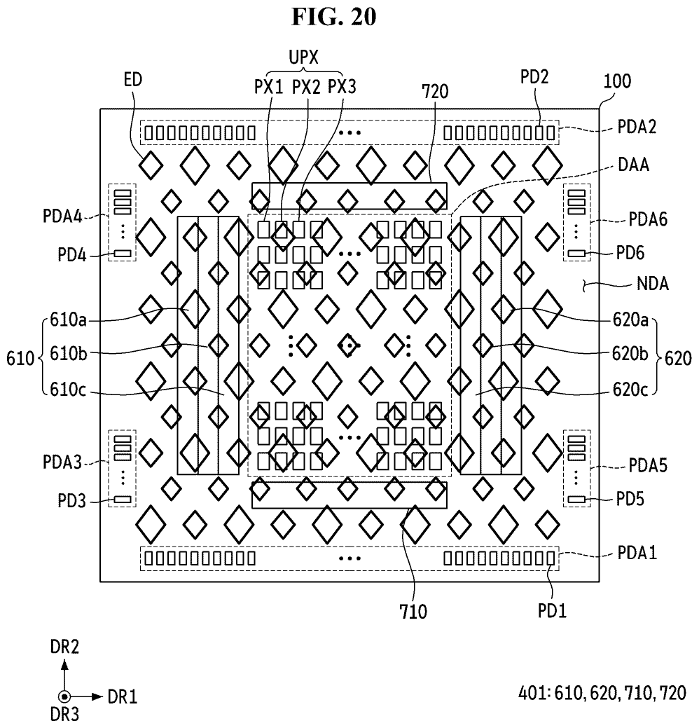

FIG. 20 is a plan view of the display panel 1000 according to one or more embodiments. For example, FIG. 20 may be a diagram further illustrating the light-emitting element ED in the display panel 100 of FIG. 4 described above.

The light-emitting element ED may overlap the first driving circuit 401 of the display panel 1000. For example, the first driving circuit 401 may overlap at least one of the scan driver 610, the emission driver 620, the first distribution circuit 710, or the second distribution circuit 720 described above. In other words, because the first driving circuit 401 includes the scan shift register 610a, the scan level shifter 610b, the scan buffer 610c, the emission shift register 620a, the emission level shifter 620b, the emission buffer 620c, the first distribution circuit 710, the second distribution circuit 720, and the like, at least one light-emitting element LE may overlap at least one of the components of the first driving circuit 401 described above. Accordingly, the light-emitting element ED may be located not only in the display area DAA but also in the non-display area NDA.

FIG. 20 illustrates an example in which some light-emitting elements LE among the plurality of light-emitting elements LE overlap the scan driver 610, the emission driver 620, the first distribution circuit 710, and the second distribution circuit 720. Accordingly, the display area DAA may be substantially expanded. Meanwhile, the pixel circuits PC for driving the light-emitting elements ED may be located in the display area DAA. The light-emitting element ED located in the non-display area NDA may be connected to the pixel circuit PC of the display area DAA. For example, the anode electrode of the light-emitting element ED in the non-display area NDA may extend to the display area DAA to be connected to the pixel circuit PC of the display area DAA.

The light-emitting elements ED may have different sizes. For example, the first electrode (or emission area) of the red light-emitting element ED providing red light, the first electrode (or emission area) of the green light-emitting element ED providing green light, and the first electrode (or emission area) of the blue light-emitting element ED providing blue light may have different sizes.

As the at least one light-emitting element ED overlaps the first driving circuit 401 in this way, the size of the display area DAA may be expanded. For example, as in the example shown in FIG. 20, when the plurality of light-emitting elements LE overlap the scan driver 610, the emission driver 620, the first distribution circuit 710, and the second distribution circuit 720, the display area DAA may be expanded to further include the scan driver 610, the emission driver 620, the first distribution circuit 710, and the second distribution circuit 720. In other words, while the above-described display area DAA of FIG. 4 is defined as an area surrounded by the scan driver 610, the emission driver 620, the first distribution circuit 710, and the second distribution circuit 720, the display area DAA of FIG. 20 may be defined as a wider area additionally including the scan driver 610, the emission driver 620, the first distribution circuit 710, and the second distribution circuit 720. Accordingly, the display area DAA of FIG. 20 may have a larger area than the display area DAA of FIG. 4. Therefore, the net die of the wafer on which the display panel 1000 is manufactured may be improved. For example, assuming that the 1.3-inch display panel 1000 is manufactured on a 12-inch wafer, the net die of the wafer when the display panel 100 with the structure of FIG. 4 is manufactured is about 74, whereas the net die of the wafer when the display panel 1000 with the structure of FIG. 20 is manufactured may be about 82. Therefore, when the display panel 1000 having a large display area as shown in FIG. 20 is manufactured on a wafer, the manufacturing cost of a display device may be reduced.

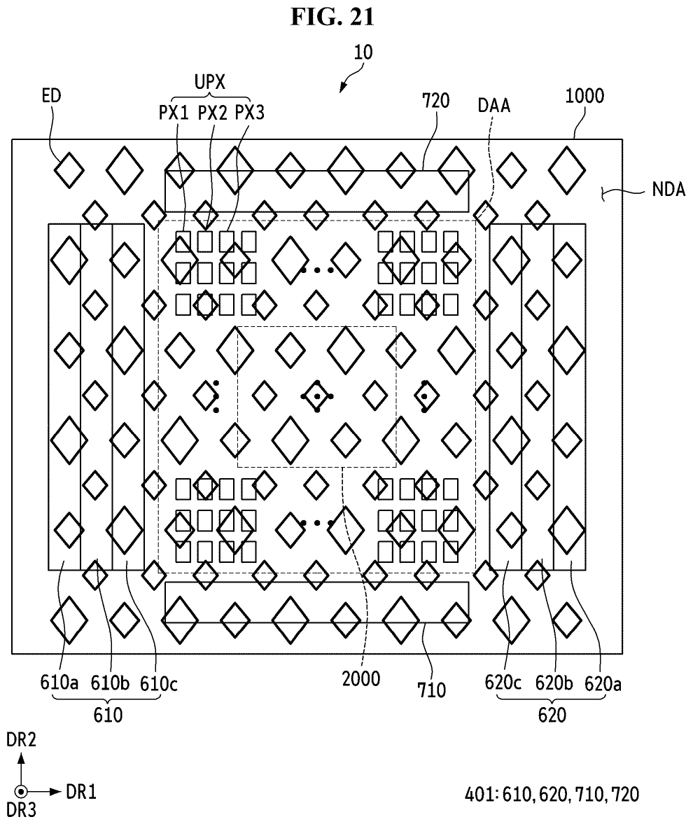

FIG. 21 is a plan view of the display panel 1000 according to one or more embodiments. For example, FIG. 21 may be a diagram further illustrating a light-emitting element in the display panel 1000 of FIG. 15 described above.

The display panel 1000 of FIG. 21 is different from the aforementioned display panel 1000 of FIG. 20 in that it does not include a plurality of pad portions.

The light-emitting element ED may overlap the first driving circuit 401 of the display panel 1000. For example, the first driving circuit 401 may overlap at least one of the scan driver 610, the emission driver 620, the first distribution circuit 710, or the second distribution circuit 720 described above. In other words, because the first driving circuit 401 includes the scan shift register 610a, the scan level shifter 610b, the scan buffer 610c, the emission shift register 620a, the emission level shifter 620b, the emission buffer 620c, the first distribution circuit 710, the second distribution circuit 720, and the like, at least one light-emitting element ED may overlap at least one of the components of the first driving circuit 401 described above. Accordingly, the light-emitting element ED may be located not only in the display area DAA but also in the non-display area NDA.

Therefore, when the display panel 1000 having a large display area DAA as shown in FIG. 21 is manufactured on a wafer, the manufacturing cost of a display device may be reduced.

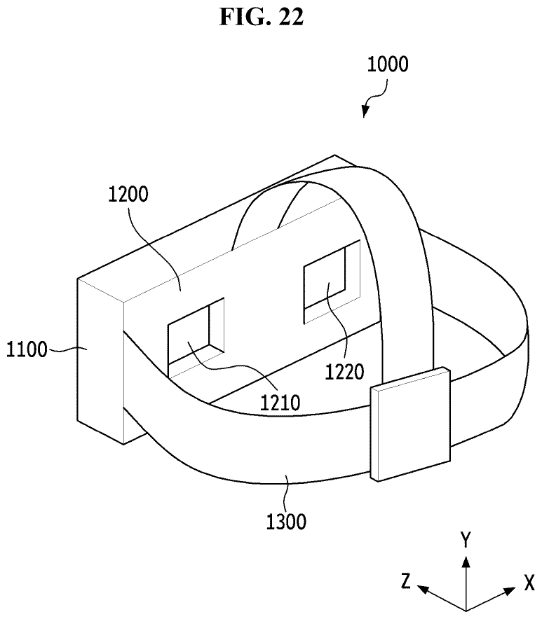

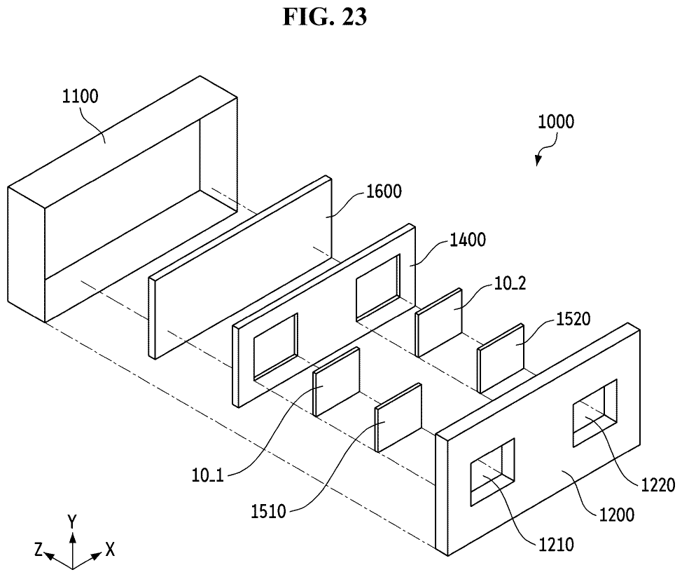

FIG. 22 is a perspective view illustrating a head-mounted display according to one or more embodiments. FIG. 23 is an exploded perspective view illustrating an example of the head-mounted display of FIG. 22.

Referring to FIGS. 22 and 23, a head-mounted display 1000 according to one or more embodiments includes a first display device 10_1, a second display device 10_2, a display device housing 1100, a housing cover 1200, a first eyepiece 1210, a second eyepiece 1220, a head-mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Because each of the first display device 10_1 and the second display device 10_2 is substantially the same as the display device 10 described in conjunction with FIGS. 1 to 21, the description of the first display device 10_1 and the second display device 10_2 will be omitted.

The first optical member 1510 may be located between the first display device 10_1 and the first eyepiece 1210. The second optical member 1520 may be located between the second display device 10_2 and the second eyepiece 1220. Each of the first optical member 1510 and the second optical member 1520 may include at least one convex lens.

The middle frame 1400 may be located between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be located between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and may transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 covers one open surface of the display device housing 1100. The housing cover 1200 may include the first eyepiece 1210 at which the user's left eye is located and the second eyepiece 1220 at which the user's right eye is located. FIGS. 22 and 23 illustrate that the first eyepiece 1210 and the second eyepiece 1220 are located separately, but the present disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

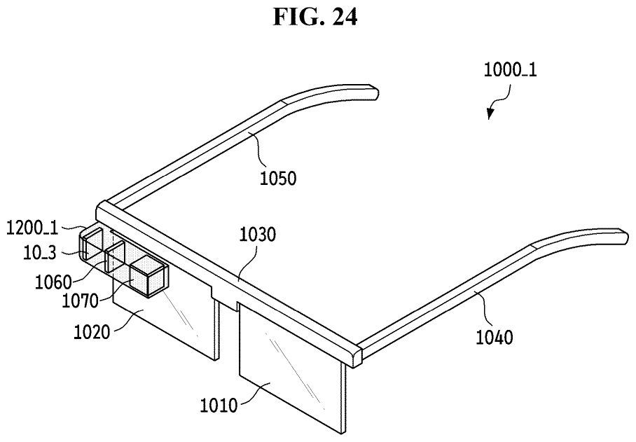

The head-mounted band 1300 serves to secure the display device housing 1100 to the user's head such that the first eyepiece 1210 and the second eyepiece 1220 of the housing cover 1200 remain located on the user's left and right eyes, respectively. When the display device housing 1200 is implemented to be lightweight and compact, the head-mounted display 1000 may be provided with an eyeglass frame as shown in FIG. 24 instead of the head-mounted band 1300.

In addition, the head-mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi® module, or a Bluetooth® module (Wi-Fi® being a registered trademark of the non-profit Wi-Fi Alliance, and Bluetooth® being a registered trademark of Bluetooth Sig, Inc., Kirkland, WA).

FIG. 24 is a perspective view illustrating a head-mounted display according to one or more embodiments.

Referring to FIG. 24, a head-mounted display 1000_1 according to one or more embodiments may be an eyeglasses-type display device in which a display device housing 1200_1 is implemented in a lightweight and compact manner. The head-mounted display 1000_1 according to one or more embodiments may include a display device 10_3, a left eye lens 1010, a right eye lens 1020, a support frame 1030, temples 1040 and 1050, an optical member 1060, an optical-path-changing member 1070, and the display device housing 1200_1.

The display device housing 1200_1 may include the display device 10_3, the optical member 1060, and the optical-path-changing member 1070. The image displayed on the display device 10_3 may be magnified by the optical member 1060, and may be provided to the user's right eye through the right eye lens 1020 after the optical path thereof is changed by the optical-path-changing member 1070. As a result, the user may view an augmented reality image, through the right eye, in which a virtual image displayed on the display device 10_3 and a real image seen through the right eye lens 1020 are combined.

Although FIG. 24 illustrates that the display device housing 1200_1 is located at the right end of the support frame 1030, the present disclosure is not limited thereto. For example, the display device housing 1200_1 may be located at the left end of the support frame 1030, and in this case, the image of the display device 10_3 may be provided to the user's left eye. Alternatively, the display device housing 1200_1 may be located at both the left and right ends of the support frame 1030, and in this case, the user may view the image displayed on the display device 10_3 through both the left and right eyes.

The display device according to the embodiment can be applied to various electronic devices. The electronic device according to one embodiment includes the display device described above and may further include modules or devices having additional functions in addition to the display device.

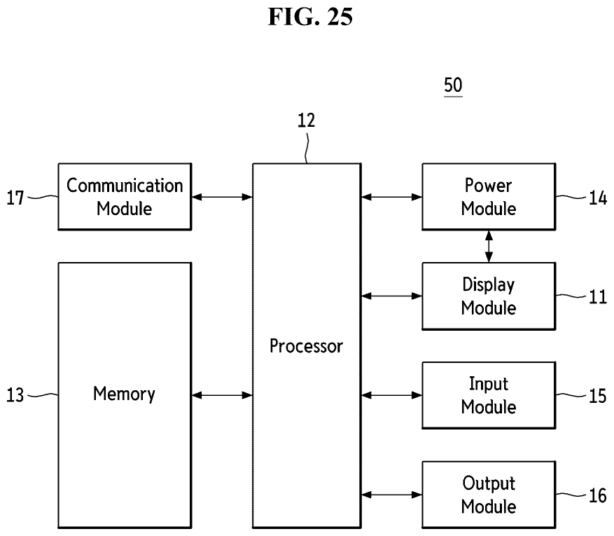

FIG. 25 is a block diagram of an electronic device according to one embodiment. Referring to FIG. 25, the electronic device 50 according to one embodiment may include a display module, a processor 12, a memory 13, and a power module 14. The electronic device 5000 may further include an input module 14, a non-image output module 15 and/or a communication module 16.

The electronic device 50 may output various information in the form of images through the display module 11. When the processor 12 executes an application stored in the memory 13, image information provided by the application may be provided to the user through the display module 1100. The power module 14 may include a power supply module such as a power adapter or a battery device, and a power conversion module that converts the power supplied by the power supply module to generate power required for the operation of the electronic device 5000. The input module 14 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 5000 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 11 other than the display device.

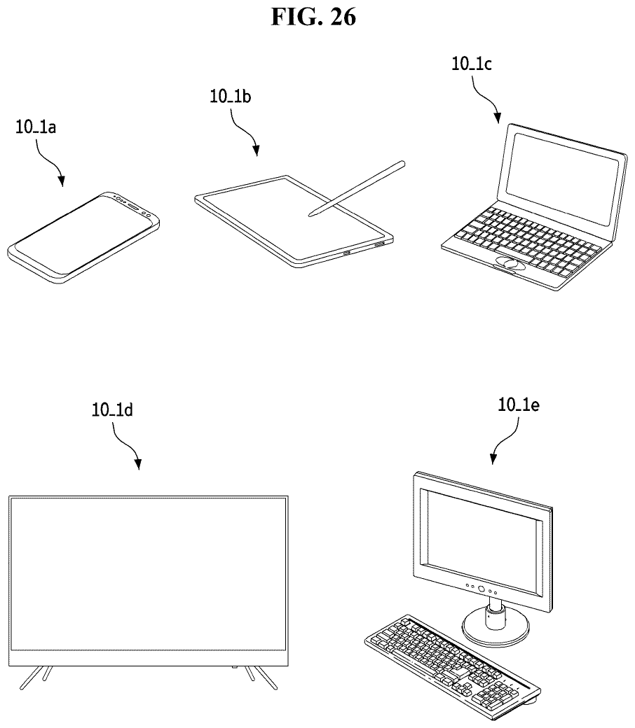

FIGS. 26, 27, and 28 are schematic diagrams of electronic devices according to various embodiments. FIGS. 26 to 28 illustrate examples of various electronic devices to which the display device according to the embodiments is applied.

FIG. 26 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

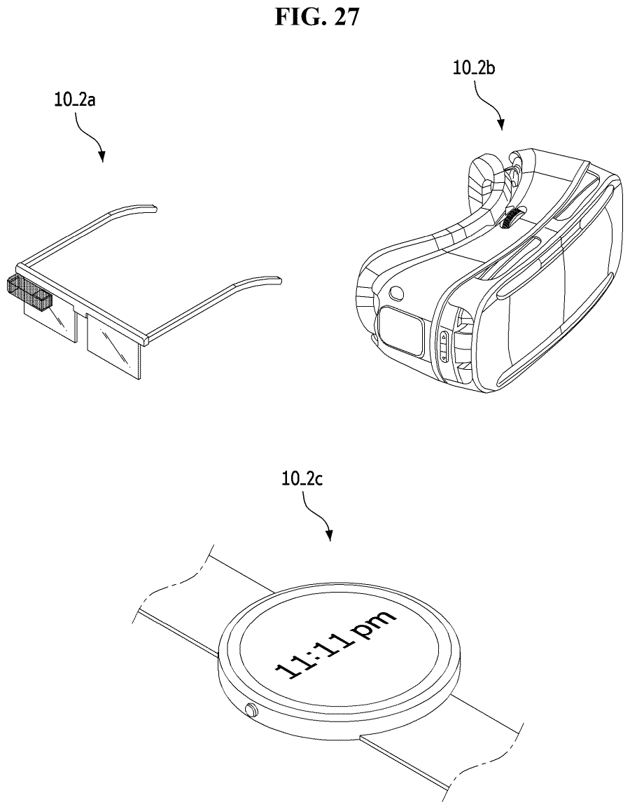

FIG. 27 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

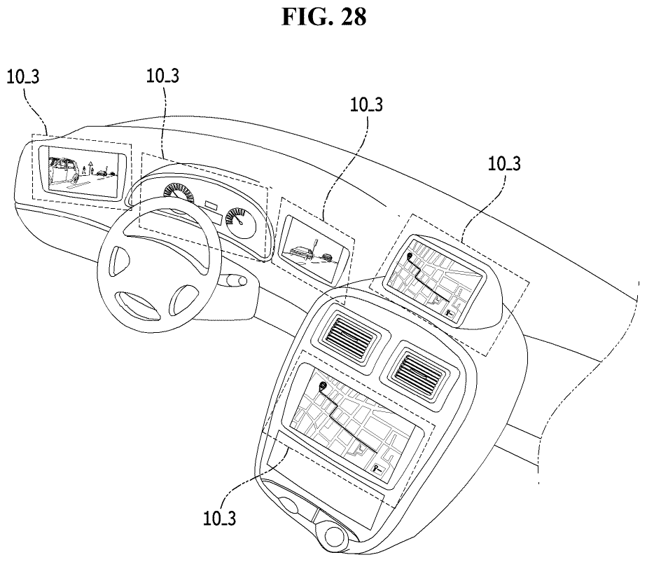

The smart watch 10_2c includes a biometric sensor as an input device, and may provide biometric information recognized by the biometric sensor to the user through the display module. FIG. 28 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

However, the aspects of the present disclosure are not restricted to the one set forth herein. The above and other aspects of the present disclosure will become more apparent to one of daily skill in the art to which the present disclosure pertains by referencing the claims.

It will be able to be understood by one of ordinary skill in the art to which the present disclosure belongs that the present disclosure may be implemented in other forms without changing the aspects of the present disclosure. Therefore, it is to be understood that the embodiments described above are illustrative rather than being restrictive in all aspects. It is to be understood that the scope of the present disclosure are defined by the claims rather than the detailed description described above and all modifications and alterations derived from the claims and their functional equivalents fall within the scope of the present disclosure.

1 what is claimed is:

1. A display device comprising:
a display panel having a display area and a non-display area;
a pixel in the display area, and comprising a pixel circuit;
a circuit board connected to the non-display area;
a first driving circuit on the display panel; and
a second driving circuit on the circuit board,
wherein the first driving circuit and the pixel circuit comprise single-type MOS transistors.

2. The display device of claim 1, wherein the first driving circuit and the pixel circuit of the pixel comprise an n-type MOS transistor or a p-type MOS transistor.

3. The display device of claim 2, wherein the display panel comprises:
a p-type semiconductor substrate;
a deep-n-well region of the p-type semiconductor substrate;
a p-well region surrounded by the deep-n-well region in plan view; and
a p-type MOS transistor on the p-well region.

4. The display device of claim 3, wherein the p-type MOS transistor comprises:
a source electrode and a drain electrode surrounded by the p-well region in plan view; and
a gate electrode above a channel region, and between the source electrode and the drain electrode in plan view.

5. The display device of claim 2, wherein the display panel comprises:
a p-type semiconductor substrate; and
an n-well region of the p-type semiconductor substrate.

6. The display device of claim 5, wherein the n-type MOS transistor comprises:
a source electrode and a drain electrode surrounded by the n-well region in plan view; and
a gate electrode above a channel region, and between the source electrode and the drain electrode in plan view.

7. The display device of claim 1, wherein the circuit board is arranged along a first edge, a second edge, and a third edge of the display panel.

8. The display device of claim 7, wherein the circuit board is further arranged along a part of a fourth edge of the display panel.

9. The display device of claim 8, wherein the display panel further comprises:
a first pad at the first edge of the non-display area of the display panel, and connected to the circuit board; and
a second pad at the second edge of the non-display area of the display panel, and connected to the circuit board.

10. The display device of claim 9, wherein the display panel further comprises:
a third pad and a fourth pad at the third edge of the non-display area of the display panel, and connected to the circuit board; and
a fifth pad and a sixth pad at the fourth edge of the non-display area of the display panel, and connected to the circuit board.

11. The display device of claim 10, wherein the circuit board defines an opening between the fifth pad and the sixth pad in plan view.

12. The display device of claim 1, wherein the pixel further comprises a light-emitting element connected to the pixel circuit, and overlapping at least a part of the first driving circuit.

13. A display device comprising:
a display panel having a display area and a non-display area, and comprising a first driving circuit in the non-display area;
a pixel in the display area, and comprising a pixel circuit;
a driver facing the display panel, and comprising a second driving circuit connected to the first driving circuit,
wherein the first driving circuit and the pixel circuit comprise single-type MOS transistors.

14. The display device of claim 13, wherein the first driving circuit and the pixel circuit comprise an n-type MOS transistor or a p-type MOS transistor,
wherein the display panel comprises:
a p-type semiconductor substrate;
a deep-n-well region of the p-type semiconductor substrate;
a p-well region surrounded by the deep-n-well region in plan view; and
a p-type MOS transistor on the p-well region.

15. The display device of claim 14, wherein the p-type MOS transistor comprises:
a source electrode and a drain electrode surrounded by the p-well region in plan view; and
a gate electrode above a channel region, and between the source electrode and the drain electrode in plan view.

16. The display device of claim 14, wherein the display panel comprises:
a p-type semiconductor substrate; and
an n-well region of the p-type semiconductor substrate,
wherein the n-type MOS transistor comprises:
a source electrode and a drain electrode surrounded by the n-well region in plan view; and
a gate electrode above a channel region, and between the source electrode and the drain electrode in plan view.

17. The display device of claim 13, wherein the display panel comprises a semiconductor substrate, and
wherein the driver is above the semiconductor substrate, and faces the semiconductor substrate,
wherein the driver is above the semiconductor substrate and overlaps the display area.

18. The display device of claim 17, wherein the second driving circuit is electrically connected to the first driving circuit and to the pixel circuit through a through hole penetrating the semiconductor substrate,
further comprising:
a connection electrode in the through hole; and
a routing line electrically connecting the connection electrode, the second driving circuit, and the pixel circuit.

19. The display device of claim 13, wherein the second driving circuit comprises a CMOS transistor,
wherein the driver comprises:
a p-type semiconductor substrate;
a deep-n-well region of the p-type semiconductor substrate;
an n-well region on the deep-n-well region; and
a p-well region on the deep-n-well region,
wherein the CMOS transistor comprises:
a p-type MOS transistor on the n-well region; and
an n-type MOS transistor on the p-well region.

20. An electronic device comprising:
a display device comprising:
a display panel having a display area and a non-display area;
a pixel in the display area, and comprising a pixel circuit;
a circuit board connected to the non-display area;
a first driving circuit on the display panel; and
a second driving circuit on the circuit board; and
an optical-path-changing member on the display device,
wherein the first driving circuit and the pixel circuit comprise single-type MOS transistors.
